(19) United States
(12) Patent Application Publication
(10) Pub. No.: US 2004/0219298 A1
(43) Pub. Date: Nov. 4, 2004

(54) Substrate processing method and substrate processing apparatus

(76) Inventors: Akira Fukunaga, Tokyo (JP); Haruko Ono, Tokyo (JP); Hiroaki Inoue, Tokyo (JP); Shohei Shima, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/769,778

(22) Filed: Feb. 3, 2004

(30) Foreign Application Priority Data
Feb. 27, 2003 (JP) 2003-51744
Mar. 31, 2003 (JP) 2003-96464

(51) Int. Cl. B05D 3/04; B05D 3/10; H01L 21/4763

(52) U.S. Cl. 427/304; 427/96.2; 427/99.5; 438/618

(57) ABSTRACT

The present invention provides a substrate processing method and a substrate processing apparatus which has reproducibility over a surface of a substrate such as a semiconductor wafer and between substrates and can manufacture semiconductor devices or the like with a high yield. According to the present invention, a substrate processing method of forming a protective film selectively on bottom surfaces and side surfaces or exposed surfaces of embedded interconnects formed in a surface of a substrate is characterized by performing a pre-plating process on the substrate, carrying out electroless plating on the surface of the substrate after the pre-plating process to form the protective film selectively on the bottom surfaces and the side surfaces or the exposed surfaces of the interconnects, and bringing the substrate into a dry state after the electroless plating.

### BACKGROUND OF THE INVENTION

1. Field of the Invention

The present invention relates to a substrate processing method and a substrate processing apparatus, and more particularly to a substrate processing method and a substrate processing apparatus used for forming, on bottom surfaces and side surfaces or exposed surfaces of embedded interconnects in which an electrical conductor (interconnect material) such as copper or silver is embedded in interconnect recesses provided in a surface of a substrate such as a semiconductor wafer, a conductive film having a function to prevent thermal diffusion of the interconnect material into an interlayer dielectric film or a function to improve adhesiveness between the interconnects and an interlayer dielectric film, or a protective film such as a magnetic film covering the interconnects by electroless plating.

A substrate processing method and a substrate processing apparatus according to the present invention is employed mainly for manufacturing semiconductor devices.

2. Description of the Related Art

As an interconnect formation process for semiconductor devices, there is getting employed a process (so-called damascene process) in which metal (interconnect material) is embedded in interconnect recesses such as trenches or contact holes. This process includes embedding aluminum or, recently, metal such as copper or silver in trenches or contact holes, which have previously been formed in an interlayer dielectric film, and then removing excessive metal by chemical mechanical polishing (CMP) for planarization.

In a case of such interconnects, for example, copper interconnects, which use copper as an interconnect material, surfaces of the interconnects made of copper are exposed to the outside after the planarization. In order to improve the reliability, there has been employed a method in which a barrier film is formed on bottom surfaces and side surfaces of the interconnects to prevent thermal diffusion of the interconnects (copper) into an interlayer dielectric film and to improve electromigration resistance of the interconnects, or a method in which an antioxidizing film is formed to prevent oxidation of the interconnects (copper) under an oxidizing atmosphere so as to produce a semiconductor device having a multilayer interconnect structure in which insulating films (oxide films) are subsequently laminated. Generally, metal such as tantalum, titanium, or tungsten, or nitride thereof has heretofore been used as this type of barrier film. Nitride of silicon has generally been used as an antioxidizing film.

As an alternative of the above methods, there has been studied a method in which bottom surfaces and side surfaces or exposed surfaces of embedded interconnects are selectively covered with a protective film made of a cobalt alloy, a nickel alloy, or the like to prevent thermal diffusion, electromigration, and oxidation of the interconnects. With regard to a non-volatile magnetic memory, it has been proposed that portions around memory interconnects are covered with a magnetic film such as a cobalt alloy or a nickel alloy in order to prevent increase of a writing current due to miniaturization. For example, a cobalt alloy, a nickel alloy, and the like are obtained by electroless plating.

For example, as shown in FIG. 1, fine interconnect recesses 4 are formed in an insulating film (interlayer dielectric film) 2 made of SiO₂ or the like, which has been deposited on a surface of a substrate W such as a semiconductor wafer. A barrier layer 6 of TaN or the like is formed on a surface of the insulating film, and then, for example, copper plating is carried out to deposit a copper film on the surface of the substrate W so as to embed copper in the interconnect recesses 4. Thereafter, CMP (chemical mechanical polishing) is carried out on the surface of the substrate W to planarize the surface of the substrate W, thereby forming interconnects 8 made of copper in the insulating film 2. A protective film (cap material) 9 of a Co—W—P alloy film, which is obtained, for example, by electroless plating, is formed selectively on surfaces of the interconnects (copper interconnects) 8 so as to protect the interconnects 8.

There will be described a process of forming a protective film (cap material) 9 of a Co—W—P alloy film selectively on surfaces of interconnects 8 by using a general planarization method and electroless plating method. First, a copper film deposited on a surface of the substrate W is polished and planarized by CMP or the like to expose surfaces of interconnects 8. Then, a polishing liquid remaining on the surface of the substrate W is cleaned and removed. Thereafter, the substrate W is immersed, for example, in dilute sulfuric acid having an ordinary temperature for about one minute to remove CMP residues such as copper remaining on a surface of an insulating film 2 or damaged layers or the like which are produced on the interconnects 8 during CMP. After the surface of the substrate W is cleaned with a cleaning liquid such as pure water, the substrate W is immersed, for example, in a PdCl₂/HCl mixed solution having an ordinary temperature for about one minute to adhere Pd as a catalyst to the surfaces of the interconnects 8 so as to activate exposed surfaces of the interconnects 8. After the surface of the substrate W is cleaned (rinsed) with pure water or the like, the substrate W is immersed, for example, in a Co—W—P plating solution at 80° C. for about 120 seconds to carry out electroless plating selectively on surfaces of the activated interconnects 8. Thereafter, the surface of the substrate W is cleaned with a cleaning liquid such as pure water. Thus, a protective film 9 made of a Co—W—P alloy film is formed selectively on the exposed surfaces of the interconnects 8 so as to protect the interconnects 8.

Meanwhile, in order to expose surfaces of interconnects by a planarization process and to form a protective film of a Co—W—P alloy film on the exposed surfaces by electroless plating, there are performed various processes including a polishing process such as CMP using slurry, a pre-plating process of a substrate with various chemical liquids, a plating process, a post-plating process, and rinsing (cleaning) processes performed between these processes, as described above. During these processes, a surface of the substrate is brought into contact with treatment liquids under various conditions. Various materials such as an oxide film, a barrier film, an interconnect material, and a catalyst coexist on the surface of the substrate. Thus, it is supposed that the substrate has quite various surface conditions.

As described above, in the presence of variety of solutions in addition to variety of substrates, certain requirements should be met so as to form a protective film (plated film) selectively on bottom surfaces and side surfaces of interconnects formed in a surface of a substrate, or on exposed surfaces of interconnects formed in a surface of a substrate while the within wafer uniformity of the film thickness is enhanced and to improve the reliability of the interconnects. In order to meet these requirements, processes and devices should be designed so that each process of polishing, cleaning, pre-plating, electroless plating, and the like should be optimized not only in consideration of characteristics in a case of coexistence of a barrier film and an interconnect material, but also in consideration of previous and subsequent processes, and that these conditions can reliably be maintained.

A plated film has heretofore been formed merely for improvement of the reliability, or conditions of a plating solution have heretofore been reviewed for this purpose. However, under the existing circumstances, there have been no suggestions on a series of operations to meet certain requirements for industrial improvement of the reliability of interconnects.

Particularly, a barrier film and an interconnect material coexist on a surface of a substrate from a state in which surfaces of interconnects are exposed by polishing to a state in which a protective film is formed by electroless plating. Various chemical liquids having quite different pHs or oxidation-reduction potentials are brought into contact with the barrier film and the interconnect material. Accordingly, the interconnect material may be corroded due to local cell effect, photovoltaic cell effect, or the like so as to increase the resistance of the interconnects or to cause defects to the interconnects.

### SUMMARY OF THE INVENTION

The present invention has been made in view of the above circumstances. It is, therefore, an object of the present invention to provide a substrate processing method and a substrate processing apparatus which has reproducibility over a surface of a substrate such as a semiconductor wafer and between substrates and can manufacture semiconductor devices or the like with a high yield.

In order to attain the above object, there is provided a substrate processing method of forming a protective film selectively on bottom surfaces and side surfaces or exposed surfaces of embedded interconnects formed in a surface of a substrate, the substrate processing method characterized by: performing a pre-plating process on the substrate; carrying out electroless plating on the surface of the substrate after the pre-plating process to form the protective film selectively on the bottom surfaces and the side surfaces or the exposed surfaces of the interconnects; and bringing the substrate into a dry state after the electroless plating.

Thus, it is possible to continuously perform a series of operations for forming a protective film on bottom surfaces and side surfaces or exposed surfaces of embedded interconnects formed in a surface of a substrate by electroless plating. Further, since the substrate is finished to a dry state, the substrate can be transferred directly to a subsequent process, and simultaneously degradation of the protective film (plated film) can be prevented before the subsequent process.

The substrate to be subjected to the pre-plating process should preferably be introduced in a dry state.

It is desirable to perform a post-treatment on the substrate after the electroless plating to improve selectivity of the protective film, and then bring the substrate into a dry state. Thus, the reproducibility of the protective film (plated film) can be improved, and a yield can be enhanced.

According to a preferred aspect of the present invention, the substrate processing method is characterized in that the pre-plating process includes a process to clean the surface of the substrate, and a process to apply a catalyst to an underlying surface, to be plated, of the substrate to activate the underlying surface to be plated after the cleaning.

Generally, a state of an underlying layer has a great influence on results of electroless plating. Depending upon conditions in a previous process, a surface of a substrate is in various states such as a state in which an oxide film is formed on an interconnect film, a state in which a metal component remains on an interlayer dielectric film, or a state in which an anticorrosive is firmly adsorbed in an interlayer dielectric film. Accordingly, by performing a proper cleaning process and activation process as a pre-plating process, an entire surface of the substrate can be cleaned, and an underlying surface to be plated can be initialized and activated so as to carry out plating with reproducibility.

According to a preferred aspect of the present invention, the substrate processing method is characterized by performing planarization of the exposed surfaces of the interconnects by either one of chemical mechanical polishing, which performs planarization by oxidation of an interconnect metal due to an oxidizing agent and mechanical removal due to abrasive particles, electrochemical polishing, which performs planarization by anode oxidation and a special electrolytic solution, or composite electrochemical polishing, which performs planarization by anode oxidation and abrasive particles, prior to the process of cleaning the surface of the substrate.

For example, the cleaning process of the surface of the substrate comprises performing a plasma treatment on the substrate under a decompressed atmosphere or an atmospheric pressure.

Since the plasma treatment is to physically treat a surface, it is possible to clean the surface of the substrate irrespective of the types of films present on the surface of the substrate.

For example, the activation process of the underlying surface to be plated is performed by light irradiation, a CVD method, or a PVD method.

It is desirable that the cleaning process of the surface of the substrate comprise bringing the surface of the substrate into contact with a chemical liquid of an inorganic acid having a pH below 2, an acid having a pH below 5 and a chelating capability, a solution having a pH below 5 to which a chelating agent is added, an alkali solution capable of removing an anticorrosive attached to the interconnects, or an alkali solution containing an amino acid, and then performing a rinsing process on the surface of the substrate with a rinsing liquid after the cleaning.

An inorganic acid having a pH below 2 includes hydrofluoric acid, sulfuric acid, hydrochloric acid, and the like. An acid solution having a pH below 5 and a chelating capability includes formic acid, acetic acid, oxalic acid, tartaric acid, citric acid, maleic acid, salicylic acid, and the like. A chelating agent to be added to an acid solution having a pH below 5 includes a halide, carboxylic acid, dicarboxylic acid, hydroxycarboxylic acid, soluble salts thereof, and the like. By performing a cleaning process using such a chemical liquid, CMP residues such as copper remaining on an insulating film or oxides on an underlying surface to be plated can be removed to improve the selectivity of plating and the adhesiveness to the underlying surface. An anticorrosive, which is generally used in a CMP process, usually becomes a factor to inhibit deposition of a plated film. When an alkali chemical liquid capable of removing an anticorrosive attached to interconnects, e.g. tetramethylammonium hydroxide (TMAH), is used, such an anticorrosive can effectively be removed. An alkali solution containing an amino acid such as glycine, cysteine, or methionine can achieve the same effects as the aforementioned acids.

For example, the rinsing liquid to rinse the surface of the cleaned substrate comprises pure water, hydrogen gas dissolved water, or electrolytic cathode water.

By performing a rinsing process on the surface of the cleaned substrate with a rinsing liquid, chemicals used in the cleaning are prevented from remaining on the surface of the substrate and inhibiting a subsequent activation process. Ultrapure water is generally used as the rinsing liquid. However, depending upon a material of the underlying surface to be plated, even if ultrapure water is used, an interconnect material may be corroded due to local cell effect or the like. In such a case, it is desirable to use, as the rinsing liquid, hydrogen gas dissolved water into which hydrogen gas is dissolved in ultrapure water, or water including no impurities and having a high reducing capability, such as electrolytic cathode water, which is obtained by performing diaphragm electrolysis on ultrapure water. Because chemicals used in the cleaning may have corrosiveness to the interconnect material or the like, it is desirable that a period of time between the cleaning process and the rinsing process be as short as possible.

It is desirable that the application of the catalyst to the underlying surface to be plated comprise bringing the underlying surface to be plated into contact with a chemical liquid containing palladium, and then performing a rinsing process on the surface of the substrate with a rinsing liquid after the catalyst application.

By applying a catalyst to the underlying surface to be plated, it is possible to enhance the selectivity of electroless plating. Various materials can be used as a catalyst metal. However, it is desirable to use palladium in view of a reaction rate, easiness of the control, or the like. Methods of applying a catalyst include a method in which an overall substrate is immersed in a catalyst liquid, and a method in which a catalyst liquid is ejected toward the surface of the substrate by a spray or the like. One of these methods can be selected depending upon the composition of a plated film, the required film thickness, or the like. Generally, the spray method is superior in reproducibility or the like to form a thin film. As with the cleaning process, if the catalyst liquid remains on the surface of the substrate, then it may cause corrosion of the interconnect material or have adverse influences on the plating process. Accordingly, it is desirable that a period of time between the catalyst application process and the rinsing process be as short as possible.

For example, the rinsing liquid to rinse the surface of the substrate to which the catalyst is applied comprises pure water, hydrogen gas dissolved water, electrolytic cathode water, or an aqueous solution containing a component in a plating solution used for the electroless plating.

As in the case of the aforementioned cleaning process, either one of pure water, hydrogen gas dissolved water, or electrolytic cathode water can be used as the rinsing liquid to rinse the surface of the substrate to which the catalyst is applied. However, in order to acclimatize the substrate prior to the subsequent plating process, an aqueous solution containing a component which is contained in the electroless plating solution, such as a reducing agent, can also be employed.

It is desirable that the catalyst be applied to the underlying surface to be plated so that the underlying surface to be plated has a palladium catalyst concentration of 0.4 to 8 μg per 1 cm².

In order to form a uniform and continuous electroless plated film on an overall substrate, the amount of catalyst applied to an underlying surface to be plated should be at least a predetermined value. If palladium is used as a catalyst, it has experimentally been confirmed by the inventors that applied palladium of at least 0.4 μg per 1 cm² of an underlying surface can meet this requirement. There has been known that when the amount of Pd applied is larger than a predetermined amount, an underlying surface is corroded so that the resistance of the overall interconnects is increased. It also has experimentally been confirmed by the inventors that such a tendency becomes more significant when palladium of at least 8 μg is applied per 1 cm² of the underlying surface.

According to a preferred aspect of the present invention, the substrate processing method is characterized by measuring an amount of chemical liquid used for the pre-plating process, analyzing composition in the pre-treatment liquid, and replenishing an insufficient component in the pre-treatment liquid.

A palladium solution or the like is relatively expensive. Accordingly, it can be considered that such a pre-treatment liquid is circulated and reused. In such a case, since active components are reduced according to progress of the treatment, it is desirable to control the concentrations and the amount of respective components.

It is desirable that a deposition rate of the protective film by the electroless plating be in a range of 10 to 200 Å per minute.

Since the plating rate has a direct influence on the productivity, it cannot be excessively low. On the other hand, if the plating rate is excessively high, the uniformity and reproducibility cannot be maintained. The protective film to protect the interconnects is generally required to have a thickness of about several tens to about several hundreds of angstroms. In such a case, it is desirable that the deposition rate be 10 to 200 Å per minute. The plating rate can be controlled based on both of composition conditions of the plating solution, such as pH, and reaction conditions, such as a reaction temperature.

It is desirable that the deposition of the protective film by the electroless plating comprise bringing the substrate into contact with a plating solution having a pH of 7 to 10 and including alkali metal but no ammonia.

A plating solution is generally heated to control reaction in electroless plating. When ammonium ions are contained in the heated plating solution, it is difficult to stably maintain the composition of the plating solution because ammonia is volatile. Accordingly, it is difficult to maintain the reproducibility of a plating rate and the composition of a plated film for a long term. When the plating solution uses an alkali metal salt as its component instead of an ammonium salt so that no ammonium ions are contained in the plating solution, then the above adverse influence can be prevented.

It is desirable that the plating solution contain tungsten in concentration of at least 1.5 g/L.

An alloy film of a nickel alloy or a cobalt alloy should contain a certain amount of tungsten in order to achieve the aforementioned protective effects. Thus, the electroless plating solution should contain at least a certain amount of tungsten. When the electroless plating solution contains at least 1.5 g/L of tungsten, the amount of tungsten can be controlled effectively in the alloy.

It is desirable that the protective film comprise an alloy film containing three elements of cobalt, tungsten, and phosphorus.

An alloy film, of a nickel alloy or a cobalt alloy, containing three elements of cobalt, tungsten, and phosphorus is effective in thin film formation because a deposition rate is relatively low. Further, a plating solution is relatively stable, and the film composition can easily be controlled. Simultaneously, the reproducibility of the film composition can readily be maintained.

It is desirable that an average composition of the alloy film be in a range of 75 to 90 atomic % of cobalt, 1 to 10 atomic % of tungsten, and 5 to 25 atomic % of phosphorus.

The composition of an alloy film containing three elements of cobalt, tungsten, and phosphorus has a trade-off relationship between contents of tungsten and phosphorus. When the amount of tungsten is increased, the plating rate is extremely lowered. Thus, the minimum composition of tungsten to achieve a protection function is at least 1 atomic %, and the maximum composition is at most 10 atomic % in view of the plating rate. Accordingly, the composition of phosphorus is 5 to 25 atomic %, and the composition of cobalt is 75 to 90 atomic %.

According to a preferred aspect of the present invention, the substrate processing method is characterized by measuring an amount of the plating solution, analyzing composition in the plating solution, and replenishing an insufficient component in the plating solution.

Respective components in the plating solution are consumed by the deposition, and a reducing agent in the plating solution is decomposed over time. Since the plating solution is heated, a composition variation is caused by evaporation of moisture or the like. Further, a small amount of liquid is taken out of the system according to the processes. Accordingly, by analyzing the pH of the plating solution or the composition of respective components in the plating solution so that the components are maintained within a certain range, the reproducibility of the film composition can be maintained.

It is desirable to measure a dissolved oxygen concentration in the plating solution and control the dissolved oxygen concentration to be constant.

According to experimental results by the inventors, if dissolved oxygen in the plating solution is not within a certain range, the reproducibility of the plating reaction is degraded, although detailed mechanisms have not been proved. Accordingly, by measuring and controlling the dissolved oxygen concentration in the plating solution, the stability of the plating reaction can be maintained.

It is desirable to lift up the substrate from the plating solution after the electroless plating process, and bring the surface of the substrate into contact with a stop solution of a neutral liquid having a pH of 6 to 7.5 to stop plating reaction.

Thus, the plating reaction is quickly stopped immediately after the substrate is lifted up from the plating solution, to thereby prevent plating unevenness from being produced on the plated film. It is desirable that this processing time be, for example, 1 to 5 seconds.

For example, the stop solution comprises pure water, hydrogen gas dissolved water, or electrolytic cathode water.

As described above, an interconnect material may be corroded due to local cell effect or the like depending upon a material of the surface. In such a case, when the plating is stopped by ultrapure water having a reducing capability, such adverse influences can be avoided.

According to a preferred aspect of the present invention, the substrate processing method is characterized in that the post-treatment of the substrate comprises rubbing the surface, to be treated, of the substrate with a surface of a cylindrical cleaning member while rotating the cleaning member about its axis.

Thus, plating residues such as fine metallic particles on an interlayer dielectric film can completely be removed to thus improve the selectivity of the plating.

According to a preferred aspect of the present invention, the substrate processing method is characterized in that the post-treatment of the substrate comprises performing planarization of the plated surface by either one of chemical mechanical polishing, electrochemical polishing, or composite electrochemical polishing.

Thus, plating residues such as fine metallic particles on an interlayer dielectric film can completely be removed to thus improve the selectivity of the plating. Further, since planarization of the surface to be plated can also be performed, a subsequent process can be facilitated.

It is desirable that the post-treatment of the substrate use a chemical liquid containing one or at least two of a surface-active agent, an organic alkali, and chelating agent.

The use of such a chemical liquid can improve the selectivity of the electroless plating more efficiently. It is desirable that the surface-active agent be nonionic, that the organic alkali be quaternary ammonium or amines, and that the chelating agent be an organic acid such as ethylenediamines or a citric acid.

It is desirable to rinse the substrate with pure water, hydrogen gas dissolved water, or electrolytic cathode water after the post-treatment of the substrate, and then dry the substrate.

As described above, an interconnect material may be corroded due to local cell effect or the like depending upon a material of the surface. In such a case, the substrate is rinsed with ultrapure water having a reducing capability, such adverse influences can be avoided.

It is desirable to control humidity of an atmosphere around the substrate by using dry air or dry inert gas when a drying process is performed to bring the substrate into a dry state.

If drying is carried out under a normal atmosphere, then moisture on the substrate is scattered over the atmosphere to increase the humidity. A large amount of moisture is adsorbed on the surface of the atmosphere even though the substrate has been subjected to the drying process. In such a state, adsorbed moisture may raise new problems such as oxidation of the interconnect portions. Further, there may be supposed problems such as generation of watermarks due to misting back in a spin-drier. Thus, when the humidity of an atmosphere is controlled with dry air or dry nitrogen at the time of drying, such adverse influences can be avoided.

It is desirable to perform a heat treatment on the dried substrate to reform the protective film.

Thus, it is possible to improve the barrier properties of the protective film (plated film) formed on the exposed surfaces of the interconnects, the adhesiveness to the interconnects, and the like. Further, when the heat treatment is added prior to a subsequent process, it is possible to minimize thermal deformation or the like of the protective film (plated film) formed on the exposed surfaces of the interconnects.

For example, the temperature of the heat treatment is in a range of 120 to 450° C.

It is desirable that the temperature required for reforming the protective film be at least 120° C. in consideration of practical processing time and not more than 450° C. in consideration of heat resistance of materials forming devices.

It is desirable to measure film thickness of the protective film formed on a plated underlying surface.

Thus, the film thickness of the protective film formed on the exposed surfaces of the interconnects is measured, and processing time of plating for a subsequent substrate is adjusted according to variations of the film thickness. Accordingly, the film thickness of the protective film formed on the exposed surfaces of the interconnects can be controlled to be constant.

According to an aspect of the present invention, there is provided a substrate processing apparatus characterized by comprising: a pre-treatment unit for performing a pre-plating process on a surface of a substrate; an electroless plating unit for carrying out electroless plating on the surface of the substrate after the pre-plating process to form a protective film selectively on bottom surfaces and side surfaces or exposed surfaces of interconnects; and a drying unit for bringing the substrate into a dry state after the electroless plating process.

Thus, a series of operations for forming a protective film on bottom surfaces and side surfaces or exposed surfaces of embedded interconnects formed in a surface of a substrate by electroless plating can be performed continuously in a single apparatus. Further, since the substrate is finished to a dry state, the substrate can be transferred directly to a subsequent process.

It is desirable to have a post-treatment unit disposed between the electroless plating unit and the drying unit for performing a post-treatment to improve selectivity of the protective film formed on the surface of the substrate.

Thus, the entire apparatus can be made compact in size as compared to a case where the respective processes are performed by separate apparatuses (treatment sections). Accordingly, a large space is not required. Further, it is possible to reduce initial cost and running cost of the apparatus and to form a protective film (plated film) with a high selectivity in a short period of processing time.

According to a preferred aspect of the present invention, the substrate processing apparatus is characterized in that the pre-treatment unit has a first pre-treatment unit for treating the surface of the substrate with a chemical liquid and removing the chemical liquid from the surface of the substrate, and a second pre-treatment unit for applying a catalyst to the surface of the substrate and removing a chemical liquid used for catalyst application from the surface of the substrate.

Surface conditions of the substrate to be introduced into the processing apparatus depend upon a previous process. However, by surface cleaning and initialization with a proper chemical liquid in the first pre-treatment unit and an activation process of catalyst application in the second pre-treatment unit, it is possible to perform a plating process irrespective of the previous process.

It is desirable that the pre-treatment unit be configured to eject a chemical liquid toward the substrate through a spray.

Catalyst application methods are considered to include an immersion method and a spray method. The spray method is superior in view of reliability or the like.

According to a preferred aspect of the present invention, the substrate processing apparatus is characterized by comprising a pre-treatment liquid management unit for measuring an amount of pre-treatment liquid held in the pre-treatment unit, analyzing composition in the pre-treatment liquid, and replenishing an insufficient component in the pre-treatment liquid.

Analyzing methods of the composition of the pre-treatment liquid include an electrode method, a titration method, an electrochemical measurement, and the like. Signals indicative of the analysis results by such methods are processed to replenish an insufficient component from a replenishment tank to the pre-treatment liquid reservoir tank using a metering pump or the like, thereby controlling the amount of the pre-treatment liquid and the composition of the pre-treatment liquid. Thus, thin film plating can be achieved with high reproducibility.

According to a preferred aspect of the present invention, the substrate processing apparatus is characterized in that the electroless plating unit has a plating tank, a plating solution circulating system, and a plating solution reservoir tank, wherein the plating solution circulating system can circulate a plating solution between the plating tank and the plating solution reservoir tank at flow rates which can be set independently at the time of a standby of plating and at the time of a plating process, wherein an amount of plating solution circulated at the time of the standby of plating is in a range of 2 to 20 L/min, and an amount of plating solution circulated at the time of the plating process is in a range of 0 to 10 L/min.

Thus, a large amount of plating solution circulated at the time of the standby of plating can be ensured so as to maintain the temperature of a plating bath in a cell to be constant, and the amount of plating solution circulated at the time of the plating process is reduced so as to deposit a protective film (plated film) having a more uniform thickness.

It is desirable to have a plating solution management unit for measuring an amount of plating solution held in the electroless plating unit, analyzing composition in the plating solution, and replenishing an insufficient component in the plating solution.

Analyzing methods of the composition of the plating solution include an absorptiometric method, a titration method, an electrochemical measurement, an electrophoretic method, and the like. Signals indicative of the analysis results by such methods are processed to replenish an insufficient component from a replenishment tank to the plating solution reservoir tank using a metering pump or the like, thereby controlling the amount of the plating solution and the composition of the plating solution. Thus, thin film plating can be achieved with high reproducibility.

It is desirable that the plating solution management unit have a dissolved oxygen concentration meter for measuring dissolved oxygen in the plating solution held in the electroless plating unit, and control dissolved oxygen concentration of the plating solution so as to be constant based on indication of the dissolved oxygen concentration meter.

Measuring methods of the dissolved oxygen concentration in the plating solution include an electrochemical method and the like. By controlling the dissolved oxygen concentration of the plating solution so as to be constant by deaeration, nitrogen blowing, or other methods, the plating reaction can be achieved with high reproducibility.

For example, the post-treatment unit employs at least one of roll scrubbing cleaning, pencil cleaning, or etching back with an etching liquid.

Thus, by applying a physical force to the surface of the substrate after the plating process or bringing a chemical liquid having an etching capability into contact with the surface of the substrate after the plating process, residues on an interlayer dielectric film can be removed completely to thus improve a yield of semiconductor devices or the like.

For example, the post-treatment unit is formed by at least one of a chemical mechanical polishing unit, an electrochemical polishing unit, or a composite electrochemical polishing unit.

Thus, by applying a physical force to the surface of the substrate after the plating process, residues on an interlayer dielectric film can be removed completely to thus improve a yield of semiconductor devices or the like. Further, planarization of the surface of the substrate after the plating process can be performed, and a subsequent substrate process can be facilitated.

For example, the drying unit comprises a spin-drier.

Thus, the substrate after the post-treatment can quickly be dried so as to enhance the productivity of the apparatus.

It is desirable that the drying unit have a dry air unit for supplying dry air to the drying unit or a dry inert gas unit for supplying dry inert gas to the drying unit.

Thus, the substrate after the post-treatment is dried thoroughly. Problems such as oxidation of the interconnect portions due to adsorbed moisture or generation of watermarks due to misting back can be avoided.

It is desirable to have a heat treatment unit for performing a heat treatment on the substrate dried in the drying unit to reform the protective film.

Thus, a series of operations for improving the barrier properties of the protective film formed on an underlying surface, to be plated, of the interconnects in the surface of the substrate and the adhesiveness to the interconnects can be performed efficiently by a single apparatus.

It is desirable to have a film thickness measurement unit for measuring film thickness of the protective film formed on the plated underlying surface.

Film thickness measurement units include an optical measurement unit, an AFM, an EDX, and the like. Signals from the film thickness measurement unit are processed to adjust a period of processing time for a plating process of a subsequent substrate, thereby controlling the film thickness of the protective film formed on the underlying surface, to be plated, of the surface of the substrate.

It is desirable to have a device for dissolving hydrogen gas in ultrapure water or a device for electrolyzing ultrapure water to supply hydrogen gas dissolved water or electrolytic cathode water to the respective units.

According to another aspect of the present invention, there is provided a substrate processing method characterized by: embedding an interconnect material in interconnect recesses formed in an insulating film on a substrate and having a barrier layer deposited thereon, removing an excess interconnect material for planarization to form embedded interconnects on a surface of the substrate; cleaning the planarized substrate immediately after a pre-plating process; carrying out electroless plating on the surface of the substrate immediately after the cleaning to form a protective film selectively on exposed surfaces of the interconnects; and bringing the substrate into a dry state after the electroless plating.

Generally, various stabilizing processes such as formation of an anticorrosive film are performed on exposed interconnects in a substrate after a planarization process. At the exposed interconnect portions after a pre-plating process, an interconnect material is so activated that the substrate should not be left between processes for a long period of time. It is desirable that the cleaning process after the pre-plating process be started in at most 10 seconds after the pre-plating process, preferably in 5 seconds, more preferably 3 seconds. Further, it is desirable that the plating process after the cleaning process be started in at most 30 seconds after the cleaning process, preferably in 10 seconds.

In order to start predetermined processes in such a short term, the pre-plating process device and the subsequent cleaning device should be single wafer processing devices to process a single substrate each time and have a mechanism to eject a treatment liquid in a spray manner. Further, it is more desirable to use a face-down device which directs a surface, to be processed, of a substrate downward because the face-down device can reduce contacting time with the treatment liquid.

According to the present invention, a series of operations for forming a protective film on exposed surfaces of embedded interconnects formed in a surface of a substrate by electroless plating can be performed continuously without any damage to an interconnect material. Further, since the substrate is finished to a dry state, the substrate can be transferred directly to a subsequent process, and simultaneously degradation of the protective film (plated film) can be prevented before the subsequent process.

It is desirable that the substrate to be subjected to the pre-plating process be brought into a dry state after the planarization.

In a case where a planarization process and an electroless plating process are independently performed, an interconnect material and a barrier layer are present adjacent to each other on the surface of the substrate after the planarization process. In this state, if the substrate is placed in a wet state, then the interconnect material is corroded due to cell effect. Accordingly, it is desirable to perform a necessary cleaning process after the planarization process and then introduce the substrate in a dry state into the plating process. It is also desirable to perform a necessary corrosion treatment to prevent oxidation and degradation of the stored interconnect material even if a drying process is performed after the planarization.

It is desirable to clean the substrate immediately after the planarization, and perform a pre-plating process on the substrate immediately after the cleaning.

Generally, various stabilizing processes such as formation of an anticorrosive film are performed on exposed interconnects in a substrate after a planarization process. However, such processes are not necessarily perfect. Depending upon subsequent storage conditions, oxidation of the interconnect material may be developed to cause an increase of the electric resistance. Further, when a firm anticorrosive film is formed, it is difficult to remove the anticorrosive film during a pre-plating process to form a protective film by electroless plating, which inhibits the protective film formation. After all, a stabilizing process on exposed interconnects after planarization and a removal process in pre-treatment of electroless plating result only in an increased number of processes and hence should be eliminated if possible.

Therefore, by performing a planarization process, an electroless plating process, and a cleaning and drying process entirely continuously, it is possible to achieve rationalization of processes and prevention of degradation of an interconnect material. In this case, it is desirable that the cleaning process after the planarization be started in at most 1 minute after the planarization, preferably 30 seconds, more preferably 10 seconds. Further, it is desirable that the pre-plating process after the cleaning be started in at most 30 seconds, preferably 10 seconds.

In order to start predetermined processes in such a short term, it is desirable to use a single wafer processing device to process a single substrate each time, more preferably a face-down device which directs a surface, to be processed, of a substrate downward for the same reasons as described above.

It is desirable that the substrate to be subjected to the planarization process be brought into a dry state after the interconnect material has been embedded in the interconnect recesses in the substrate.

In a case where a planarization process and an electroless plating process are continuously performed, a substrate in which an interconnect material is embedded in interconnect recesses is introduced. In such a substrate, the interconnect material is likely to elute from the surface in a wet state so as to cause contamination around the eluted portions. Accordingly, it is necessary to introduce a substrate in a dry state after the embedding. Further, in order to prevent cross contamination during a transferring process, it is more desirable to remove an interconnect material deposited on a peripheral portion of the substrate within a predetermined range by etching or the like.

For example, the interconnect material comprises copper, copper alloy, silver, or silver alloy.

Various materials can be used as an interconnect material. However, semiconductor devices that are required to protect interconnects with a protective film formed by electroless plating are generally limited to those which are highly integrated. By using copper, copper alloy, silver, or silver alloy as an interconnect material for semiconductor devices that are highly integrated, it is possible to increase the speed and the density of the semiconductor devices.

For example, the barrier layer is made of at least one of titanium, tantalum, tungsten, and a compound thereof.

For example, when copper, copper alloy, silver, or silver alloy is used as an interconnect material, then at least one of titanium, tantalum, tungsten, and compounds thereof is selected as a material for a barrier layer (barrier metal). The barrier layer includes a case in which a nitride of tantalum is formed at an interface with an insulating film, and a nitrogen content is reduced so as to eventually make a surface of the barrier layer tantalum.

For example, the protective film is made of cobalt, cobalt alloy, nickel, or alloy of nickel.

Cobalt, cobalt alloy, nickel, or nickel alloy may be used as a material having a function as a protective film to selectively cover and protect surfaces of interconnects. Particularly, it is desirable to use a ternary alloy containing, as components, each of (1) cobalt or nickel, (2) molybdenum or tungsten, and (3) phosphorus or boron. Such an alloy is effective in thin film formation because a deposition rate is relatively low. Further, a plating solution is relatively stable, and the film composition can easily be controlled. Simultaneously, the reproducibility of the film composition can readily be maintained.

It is desirable that cleaning the substrate after the planarization and/or after the pre-plating process is carried out by using a cleaning liquid such that a potential difference between the exposed surfaces of the interconnects and an exposed surface of the barrier layer is not more than 200 mV when the substrate is immersed therein.

Thus, even with any combination of interconnects (material) and a barrier layer (material), it is possible to prevent the interconnects from being selectively corroded during the substrate cleaning (rinsing) process after the pre-plating process, and to prevent an increase of the interconnect resistance or defects of the interconnects.

For example, the cleaning liquid comprises ultrapure water from which dissolved oxygen is removed.

It is desirable to use a cleaning liquid that is inert to both of the barrier layer and the interconnects and does not produce a large potential difference therebetween when both of the barrier layer and the interconnects are immersed therein. Ultrapure water from which dissolved oxygen is removed can meet this requirement.

The cleaning liquid may comprise ultrapure water in which hydrogen gas is dissolved.

By dissolving hydrogen gas in ultrapure water, it is possible to lower potentials to both of the barrier layer and the interconnects and to reliably reduce a potential difference produced between the barrier layer and the interconnects when the barrier layer and the interconnects are immersed simultaneously in the ultrapure water. Methods of dissolving hydrogen gas include (1) a method of dissolving hydrogen gas via a as dissolving membrane in ultrapure water, and (2) a method of electrolyzing ultrapure water to produce hydrogen gas and dissolving the hydrogen gas directly in ultrapure water. Both of the methods can be employed. During a manufacturing process of ultrapure water, ultraviolet irradiation may be performed to decompose and remove dissolved organic matter, and the dissolved hydrogen concentration may be increased according to the decomposition reaction. The present invention also includes such possibility.

It is desirable that the removing the excess interconnect material for planarization be carried out by a chemical mechanical polishing method using a polishing liquid such that a surface potential when the barrier layer is immersed therein is nobler than a surface potential when the interconnect material is immersed therein.

When an interconnect material on the substrate is polished so that surfaces of the embedded interconnects are exposed by chemical mechanical polishing method using a polishing liquid such that a surface potential when a barrier layer is immersed therein is nobler than a surface potential when an interconnect material is immersed therein, then the interconnect material is preferentially oxidized to suppress oxidation near the barrier layer, thereby preventing V-shaped corrosion (recesses) from being generated at an interface between the barrier layer and the interconnects. Thus, when a protective film is formed selectively by electroless plating, it is possible to prevent defects such as plating defects due to the aforementioned V-shaped corrosion.

The removing the excess interconnect material for planarization may be carried out by a chemical mechanical polishing method using a polishing liquid such that a surface potential when the barrier layer is immersed therein is less noble than a surface potential when the interconnect material is immersed therein, and in the pre-plating process before the electroless plating, the substrate may be treated with a treatment liquid such that a surface potential when the barrier layer is immersed therein is nobler than a surface potential when the interconnect material is immersed therein.

When an interconnect material on the substrate is polished and planarized by chemical mechanical polishing using a polishing liquid such that a surface potential when a barrier layer is immersed therein is less noble than a surface potential when an interconnect material is immersed therein, then V-shaped corrosion (recesses) may be generated at an interface between the barrier layer and the interconnect material because the interconnect material is preferentially oxidized near the barrier layer. If a protective film is formed selectively with the V-shaped corrosion by electroless plating, then plating is not carried out due to the fact that a polishing liquid or a cleaning liquid remains in the V-shaped recesses, thereby causing defects. Accordingly, before electroless plating, the substrate is subjected to a treatment liquid such that a surface potential when the barrier layer is immersed therein is nobler than a surface potential when the interconnect material are immersed therein. Thus, the interconnects are slightly etched to eliminate the V-shaped recesses so that a polishing liquid or a cleaning liquid does not remain on the substrate. Defects of the protective film are prevented from being generated due to the presence of the aforementioned V-shaped corrosion (recesses).

According to a preferred aspect of the present invention, the substrate processing method is characterized in that the removing the excess interconnect material for planarization includes a process of disposing a substrate and a conductive polishing tool in a polishing liquid so as to face each other, and treating the substrate while the substrate serves as a polarized anode whereas the polishing tool serves as a polarized cathode.

According to a preferred aspect of the present invention, the substrate processing method is characterized in that the removing the excess interconnect material for planarization includes a process of disposing a substrate and a cathode in ultrapure water so as to face each other while an ion exchanger is interposed between the substrate and the cathode, and treating the substrate while the substrate serves as a polarized anode.

It is desirable that at least one of the respective processes and transferring processes therebetween be performed in a shaded state.

According to another aspect of the present invention, there is provided a substrate processing apparatus characterized by comprising: a planarization unit for removing an excess interconnect material and a barrier layer deposited on a portion other than interconnect recesses for planarization in a surface of a substrate, the barrier layer being deposited on surfaces of the interconnect recesses, the interconnect material being embedded in the interconnect recesses to form embedded interconnects on the surface of the substrate; a cleaning unit for cleaning the substrate after the planarization; a pre-treatment unit for performing a pre-plating process on the surface of the cleaned substrate; an electroless plating unit for carrying out electroless plating on the surface of the substrate after the pre-treatment to form the protective film selectively on exposed surfaces of the embedded interconnects; and a drying unit for bringing the substrate into a dry state after the electroless plating process.

Thus, by connecting a planarization unit and an electroless plating unit for forming a protective film via a cleaning unit and a pre-treatment unit, the substrate can be processed continuously. Accordingly, a protective film having a necessary function can be provided without any damage to the interconnect material. Further, since the substrate after the protective film is provided can be taken out in a dry state, it can be introduced directly to a subsequent process.

It is desirable to have a post-treatment unit disposed between the electroless plating unit and the drying unit for performing a post-treatment to improve selectivity of the protective film formed on the surface of the substrate.

Generally, a necessary pre-treatment is performed so that electroless plating is selectively carried out only on interconnect portions in a pre-plating process unit. Nevertheless, the selectivity may be insufficient. Particularly, when the dimension of an insulating film is reduced between the interconnects, a little contamination at those portions causes a leak current. Accordingly, it is desirable to provide a post-treatment unit to enhance the selectivity after the electroless plating unit, thereby performing post-treatment to improve the selectivity.

According to a preferred aspect of the present invention, the substrate processing apparatus is characterized in that the pre-treatment unit has a first pre-treatment unit for treating the surface of the substrate with a chemical liquid and removing the chemical liquid from the surface of the substrate, and a second pre-treatment unit for applying a catalyst to the surface of the substrate and removing a chemical liquid used for catalyst application from the surface of the substrate.

Exposed interconnects after polishing may be oxidized by an oxidizing agent in a polishing liquid or damaged by a polishing agent. These become problematic as a design rule becomes strict. Accordingly, as a pre-treatment unit, there are provided a first pre-treatment unit to initialize these problems by a chemical liquid process and a second pre-treatment unit to activate exposed surfaces of the interconnects by catalyst application.

For example, the planarization unit is formed by at least one of a chemical mechanical polishing unit, an electrochemical polishing unit, and a composite electrochemical polishing unit.

There may be various types of planarization units. A chemical mechanical polishing unit is generally used as a planarization unit. However, a low pressure will be required when a so-called low-k material is handled, In such a case, it is desirable to apply an electrochemical polishing unit, which carries out polishing only due to electrochemical effect, or a composite electrochemical polishing unit, which combines mechanical effect due to a polishing agent with the electrochemical effect.

It is desirable to have a deposition unit for depositing an interconnect material on the interconnect recesses in the surface of the substrate prior to the planarization unit.

In a substrate having an interconnect material deposited on a surface thereof, the interconnect material is attached to an entire surface of the substrate. Thus, the substrate is likely to contaminate ambient portions. Accordingly, a series of operations should be performed without transfer between processes. The provision of a deposition unit prior to the planarization unit enables such operations.

It is desirable that the deposition unit comprises at least a plating unit.

There are various deposition methods of an interconnect material. However, a plating process, preferably an electroplating process, is suitable for deposition of an interconnect material because subsequent polishing and protective film formation are wet processes. Thus, a plating unit is suitable for a deposition unit provided prior to the polishing unit.

### BRIEF DESCRIPTION OF THE DRAWINGS

FIG. 1 is a cross-sectional view showing a state in which a protective film is formed by electroless plating.

FIG. 2 is a horizontal arrangement view of a substrate processing apparatus according to an embodiment of the present invention.

FIG. 3 is a process flow chart in the substrate processing apparatus shown in FIG. 2.

FIG. 4 is a front view of a pre-treatment unit at the time of substrate delivery.

FIG. 5 is a front view of the pre-treatment unit at the time of a chemical liquid process.

FIG. 6 is a front view of the pre-treatment unit at the time of rinsing.

FIG. 7 is a cross-sectional view showing a processing head of the pre-treatment unit at the time of substrate delivery.

FIG. 8 is an enlarged view of a portion A of FIG. 7.

FIG. 9 is a view of the pre-treatment unit when the substrate is fixed, which corresponds to FIG. 8.

FIG. 10 is a schematic diagram of the pre-treatment unit.

FIG. 11 is a cross-sectional view showing a substrate head of an electroless plating unit when a substrate is delivered.

FIG. 12 is an enlarged view of a portion B of FIG. 11.

FIG. 13 is a view of the substrate head of the electroless plating unit when the substrate is fixed, which corresponds to FIG. 12.

FIG. 14 is a view of the substrate head of the electroless plating unit at the time of plating, which corresponds to FIG. 12.

FIG. 15 is a front view showing, in a partially cutaway manner, a plating tank of the electroless plating unit when a plating tank cover is closed.

FIG. 16 is a cross-sectional view showing a cleaning tank of the electroless plating unit.

FIG. 17 is a schematic diagram of the electroless plating unit.

FIG. 18 is a vertical cross-sectional view showing a post-treatment and drying unit.

FIG. 19 is a plan view showing the post-treatment and drying unit.

FIGS. 20A through 20D are views showing an example of forming copper interconnects in a semiconductor device in a processing order.

FIG. 21 is a horizontal arrangement view showing a substrate processing apparatus (manufacturing apparatus for semiconductor devices) according to another embodiment of the present invention.

FIG. 22 is a process flow chart in the substrate processing apparatus shown in FIG. 21.

FIG. 23A is a diagram showing a state in which V-shaped corrosion is generated at an interface between a barrier layer and an interconnect, and FIG. 23B is a diagram showing a state in which a protective film is formed in the state shown in FIG. 23A.

FIG. 24A is a diagram showing a state in which V-shaped corrosion generated at the interface with the barrier layer and the interconnect is eliminated by slightly etching the interconnect, and FIG. 24B is a diagram showing a state in which a protective film is formed in the state shown in FIG. 24A.

FIG. 25 is a schematic view showing an example of a CMP device forming a polishing unit.

FIG. 26 is a schematic front view showing a portion near a reversing machine of a film thickness measurement unit.

FIG. 27 is a plan view of a reversing arm in the film thickness measurement unit.

FIG. 28 is a plan view showing an electroplating device forming a first plating unit.

FIG. 29 is a cross-sectional view taken along a line of A-A in FIG. 28.

FIG. 30 is a cross-sectional view of a substrate holder and a cathode portion of the electroplating device shown in FIG. 28.

FIG. 31 is a cross-sectional view of an electrode arm portion of the electroplating device shown in FIG. 28.

FIG. 32 is a plan view of the electrode arm portion of the electroplating device shown in FIG. 28 without a housing.

FIG. 33 is a schematic view showing an anode and a plating solution impregnated material of the electroplating device shown in FIG. 28.

FIG. 34 is a plan arrangement view showing a substrate processing apparatus (manufacturing apparatus for semiconductor devices) according to still another embodiment of the present invention.

### DETAILED DESCRIPTION OF THE PREFERRED EMBODIMENTS

Embodiments according to the present invention will be described below with reference to the drawings.

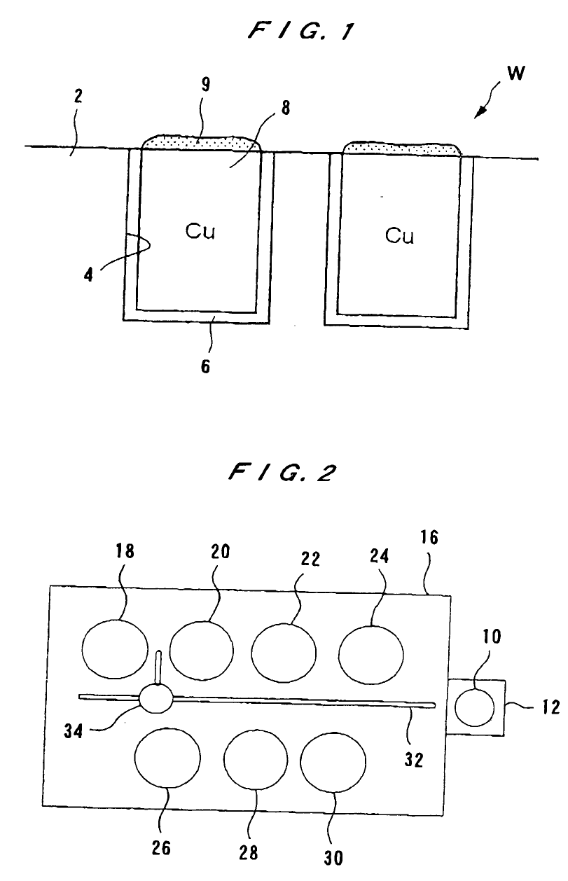

FIG. 2 shows a horizontal arrangement of a substrate processing apparatus according to an embodiment of the present invention. As shown in FIG. 2, this substrate processing apparatus has a loading/unloading unit 12 for placing and receiving a substrate cassette 10 housing substrates W (see FIG. 1) each having interconnects 8 made of copper or the like formed in interconnect recesses 4 formed in a surface thereof A first pre-treatment unit 18 for performing a pre-plating process of a substrate W, i.e., for cleaning a surface of a substrate W, a second pre-treatment unit 20 for applying a catalyst to exposed surfaces of cleaned interconnects 8 to activate the exposed surfaces, an electroless plating unit 22 for performing an electroless plating process on the surface (surface to be processed) of the substrate W, and a post-treatment unit 24 for performing a post-treatment of the substrate W to improve the selectivity of a protective film 9 (see FIG. 1) formed on the surfaces of the interconnects 8 by the electroless plating process are disposed in series along one of long sides of a rectangular housing 16 having an exhaust system.

A drying unit 26 for drying the substrate W after the post-treatment, a heat treatment unit 28 for performing a heat treatment (annealing) on the dried substrate W, and a film thickness measurement unit 30 for measuring film thickness of the protective film 9 formed on the surfaces of the interconnects 8 are disposed in series along the other of the long sides of the housing 16. Further, a transfer robot 34 movable along a rail 32 in parallel to the long sides of the housing 16 and for delivering a substrate between these units and the substrate cassette 10 placed on the loading/unloading unit 12 is disposed so as to be interposed between these units linearly arranged.

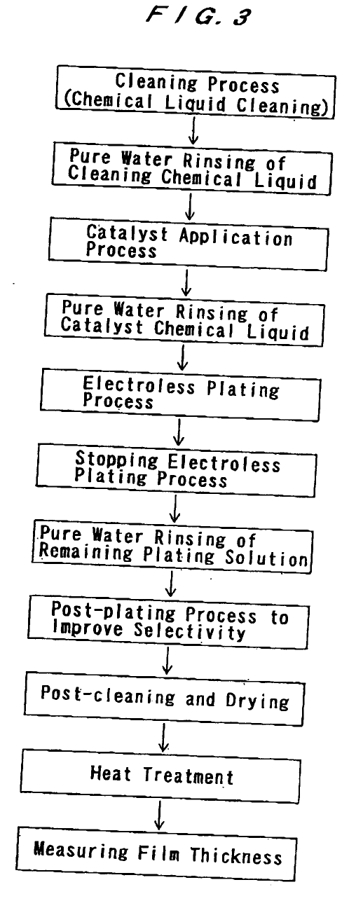

Next, a series of electroless plating processing by this substrate processing apparatus will be described with reference to FIG. 3. In this example, as shown in FIG. 1, a protective film (cap material) 9 of a Co—W—P alloy film is selectively formed to protect the interconnects 8.

First, a substrate W having interconnects 8 formed in a surface thereof is taken by the transfer robot 34 out of the substrate cassette 10, which houses substrates W in a state such that front surfaces of the substrates W face upward (in a face-up manner), placed on the loading/unloading unit 12, and is transferred to the first pre-treatment unit 18. In the first pre-treatment unit 18, the substrate W is held in a face-down manner, and a cleaning process (chemical liquid cleaning process) is performed as a pre-plating process on a surface of the substrate W. Specifically, a chemical liquid such as a dilute H₂SO₄ solution, for example at 25° C., is sprayed toward the surface of the substrate W to remove CMP residues such as copper remaining on a surface of an insulating film 2 (see FIG. 1) or oxides on an interconnect film. Thereafter, the surface of the substrate W is rinsed (cleaned) with a rinsing liquid such as pure water to remove a cleaning liquid remaining on the surface of the substrate W.

As a chemical liquid, there may be used an inorganic acid having a pH below 2, such as hydrofluoric acid, sulfuric acid, or hydrochloric acid, an acid solution having a pH below 5 and a chelating capability, such as formic acid, acetic acid, oxalic acid, tartaric acid, citric acid, maleic acid, or salicylic acid, or an acid solution having a pH below 5 to which a chelating agent such as a halide, carboxylic acid, dicarboxylic acid, hydroxycarboxylic acid, or soluble salts thereof is added. By performing a cleaning process using such a chemical liquid, CMP residues such as copper remaining on an insulating film or oxides on an underlying surface to be plated can be removed to improve the selectivity of plating and the adhesiveness to the underlying surface. An anticorrosive, which is generally used in a CMP process, usually becomes a factor to inhibit deposition of a plated film. When an alkali chemical liquid capable of removing an anticorrosive attached to interconnects, e.g. tetramethylammonium hydroxide (TMAH), is used, such an anticorrosive can effectively be removed. An alkali solution containing an amino acid such as glycine, cysteine, or methionine can achieve the same effects as the aforementioned acids.

Further, when a surface of the substrate W is rinsed (cleaned) with a rinsing liquid after the cleaning process, chemicals used in the cleaning process are prevented from remaining on the surface of the substrate W and inhibiting a subsequent activation process. Ultrapure water is generally used as the rinsing liquid. However, depending upon a material of the underlying surface to be plated, even if ultrapure water is used, an interconnect material may be corroded due to local cell effect or the like. In such a case, it is desirable to use, as the rinsing liquid, hydrogen gas dissolved water into which hydrogen gas is dissolved in ultrapure water, or water including no impurities and having a high reducing capability, such as electrolytic cathode water, which is obtained by performing diaphragm electrolysis on ultrapure water. Because chemicals used in the cleaning process may have corrosiveness to the interconnect material or the like, it is desirable that a period of time between the cleaning process and the rinsing process be as short as possible.

In this embodiment, a chemical liquid is used to perform a cleaning process (pre-plating process) on surfaces of the interconnects 8. However, a plasma treatment may be carried out on a substrate under a decompressed atmosphere or an atmospheric pressure so as to perform a cleaning process on surfaces of the interconnects 8.

Next, the substrate W after the cleaning process and the rinsing process is transferred to the second pre-treatment unit 20 by the transfer robot 34. In the second pre-treatment unit 20, the substrate W is held in a face-down manner, and a catalyst application process is performed on the surface of the substrate W. Specifically, a mixed solution of PdCl₂/HCl or the like, for example at 25° C., is ejected toward the surface of the substrate W to adhere Pd as a catalyst to the surfaces of the interconnects 8. More specifically, Pd cores are formed as catalyst cores (seeds) on the surfaces of the interconnects 8 to activate exposed surfaces of the interconnects 8. Then, a catalyst chemical liquid remaining on the surface of the substrate W is rinsed (cleaned) with a rinsing liquid such as pure water.

An inorganic or organic acid solution containing Pd is used as the chemical liquid (catalyst chemical liquid). If a Pd content in the catalyst liquid is excessively low, then the catalyst density of the underlying surface to be plated becomes low, so that plating cannot be carried out. If the Pd content is excessively high, then defects such as pitching are caused to the interconnects 8.

In order to form a uniform and continuous electroless plated film on an overall substrate, the amount of catalyst applied to an underlying surface to be plated should be at least a predetermined value. If palladium is used as a catalyst, it has experimentally been confirmed that applied palladium of at least 0.4 μg per 1 cm² of an underlying surface can meet this requirement. There has been known that when the amount of Pd applied is larger than a predetermined amount, an underlying surface is eroded so that the resistance including the underlying surface is increased. It also has experimentally been confirmed that such a tendency becomes more significant when palladium of at least 8 μg is applied per 1 cm² of the underlying surface.

Thus, when a catalyst is applied to the surface of the substrate W, it is possible to enhance the selectivity of electroless plating. Various materials can be used as a catalyst metal. However, it is desirable to use Pd in view of a reaction rate, easiness of the control, or the like. Methods of applying a catalyst include a method in which an overall substrate is immersed in a catalyst liquid, and a method in which a catalyst liquid is ejected toward the surface of the substrate by a spray or the like. One of these methods can be selected depending upon the composition of a plated film, the required film thickness, or the like. Generally, the spray method is superior in reproducibility or the like to form a thin film.

A palladium solution or the like is relatively expensive. Accordingly, it can be considered that such a pretreatment liquid is circulated and reused. In such a case, active components are reduced according to progress of the treatment, and the pre-treatment liquid is taken out due to attachment of the pre-treatment liquid to substrates. Accordingly, it is desirable to control the concentrations and the amount of respective components.

Thus, it is desirable to provide a pre-treatment liquid management unit (not shown) for analyzing the composition of the pre-treatment liquid and adding insufficient components. Specifically, a chemical liquid used in the cleaning process is mainly composed of acid or alkali. For example, a pH of the chemical liquid can be measured, a decreased content can be replenished from a difference between a preset value and the measured value, and a decreased amount can be replenished using a liquid level meter provided in a chemical liquid reservoir tank. Further, with respect to a catalyst liquid, for example, in a case of an acid palladium solution, the amount of acid can be measured by its pH, the amount of palladium can be measured by a titration method or nephelometry, and a decreased amount can be replenished in the same manner as described above.

Further, in order to improve the selectivity, it is necessary to remove Pd remaining on the interlayer dielectric film 2 and the interconnects 8. Generally, pure water rinsing is employed for this purpose. As with the cleaning process, if a catalyst liquid remains on the surface of the substrate, then it may cause corrosion of the interconnect material or have adverse influences on the plating process. Accordingly, it is desirable that a period of time between the catalyst application process and the rinsing process be as short as possible. As in the case of the cleaning process, either one of pure water, hydrogen gas dissolved water, or electrolytic cathode water can be used as the rinsing liquid. However, in order to acclimatize the substrate prior to the subsequent plating process, an aqueous solution containing components which are contained in the electroless plating solution can also be employed.

In the present embodiment, a chemical liquid is used in the activation process of Pd attachment to the surfaces of the interconnects 8. However, the activation process may be performed by light irradiation, a CVD method, or a PVD method.

The substrate W to which a catalyst is applied and which has been subjected to the rinsing process is transferred to the electroless plating unit 22 by the transfer robot 34. In the electroless plating unit 22, the substrate W is held in a face-down manner, and an electroless plating process is performed on the surface of the substrate W. Specifically, the substrate W is immersed, for example, in a Co—W—P plating solution at 80° C. for about 120 seconds to carry out electroless plating (electroless Co—W—P cap plating) selectively on surfaces of the activated interconnects 8 so as to selectively form a protective film (cap material) 9. The composition of the plating solution is as follows.

Composition of Plating Solution

CoSO₄.7H₂O: 14 g/L

Na₃C₆H₅O₇.2H₂O: 70 g/L

H₃BO₃: 40 g/L

Na₂WO₄.2H₂O: 12 g/L

NaH₂PO₂.H₂O: 21 g/L

pH: 9.5

It is desirable to use a plating solution having a pH of 7 to 10 and including a sodium element but no ammonium ions. A plating solution is generally heated to control reaction in electroless plating. When ammonium ions are contained in the heated plating solution, it is difficult to stably maintain the composition of the plating solution because ammonia is volatile. Accordingly, it is difficult to maintain the reproducibility of a plating rate and the composition of a plated film for a long term. When the plating solution uses, for example, an alkali metal salt as its component instead of an ammonium salt so that no ammonium ions are contained in the plating solution, then the above adverse influence can be prevented.

Here, it is desirable that a deposition rate of a protective film 9 by electroless plating be 10 to 200 Å per minute. Since the plating rate has a direct influence on the productivity, it cannot be excessively low. On the other hand, if the plating rate is excessively high, the uniformity and reproducibility cannot be maintained. The protective film 9 is generally required to have a thickness of about several tens to about several hundreds of angstroms. In such a case, it is desirable that the deposition rate be 10 to 200 Å per minute. The plating rate can be controlled based on both of composition conditions of the plating solution, such as pH, and reaction conditions, such as a reaction temperature.

It is desirable to use a plating solution containing W in its composition at a concentration of at least 1.5 g/L. An alloy film of a Ni alloy or a Co alloy should contain a certain amount of W in order achieve a function as a protective film 9. Thus, the plating solution should contain at least a certain amount of W. When the plating solution contains at least 1.5 g/L, the amount of W can be controlled effectively in the alloy.

Respective components in the plating solution are consumed by the deposition, and a reducing agent in the plating solution is decomposed over time. Since the plating solution is heated, a composition variation is caused by evaporation of moisture or the like. Accordingly, it is desirable that the pH of the plating solution or the composition of respective components in the plating solution be analyzed while the amount of plating solution is measured, and that insufficient components in the plating solution be replenished to maintain the components within a certain range. Thus, the reproducibility of the film composition can be maintained.

According to experimental results, if dissolved oxygen in the plating solution is not within a certain range, the reproducibility of the plating reaction is degraded, although detailed mechanisms have not been proved. Accordingly, it is desirable that the concentration of dissolved oxygen in the plating solution is measured and controlled so as to be constant. Thus, the stability of the plating reaction can be maintained.

A plating solution management unit (not shown) having an analysis device required for management of the plating solution and a replenishment mechanism of plating components can be provided.

When a pre-treatment liquid and a plating solution are used repeatedly, a specific component may be accumulated by external introduction or decomposition of the plating solution to cause degraded reproducibility of the plating or a degraded film. By adding a mechanism for selectively removing such a specific component, it is possible to prolong the lifetime of the liquid and improve the reproducibility.

It is desirable that the protective film 9 be formed by an alloy film containing three elements of Co, W, and P as described in the present embodiment. This is because an alloy film, of a Ni alloy or a Co alloy, containing three elements of Co, W, and P is effective in thin film formation because a deposition rate is relatively low. Further, a plating solution is relatively stable, and the film composition can easily be controlled. Simultaneously, the reproducibility of the film composition can readily be maintained.

Thus, when the protective film 9 is formed by an alloy film containing three elements of Co, W, and P, it is desirable that an average composition of the protective film (alloy film) 9 be in a range of Co: 75 to 90 atomic %, W: 1 to 10 atomic %, and P: 5 to 25 atomic %. The composition of an alloy film containing three elements of Co, W, and P has a trade-off relationship between the contents of W and P. When the amount of W is increased, the plating rate is extremely lowered. Thus, the minimum composition of W to achieve a protection unction is at least 1 atomic %, and the maximum composition is at most 10 atomic % in view of the plating rate. Accordingly, the composition of P is 5 to 25 atomic %, and the composition of Co is 75 to 90 atomic %.

Then, after the substrate W is lifted up from the plating solution, a stop solution of a neutral liquid having a pH of 6 to 7.5 is brought into contact with the surface of the substrate W to stop the electroless plating process. Thus, the plating reaction is quickly stopped immediately after the substrate W is lifted up from the plating solution, to thereby prevent plating unevenness from being produced on the plated film. It is desirable that this processing time be, for example, 1 to 5 seconds. Pure water, hydrogen gas dissolved water, or electrolytic cathode water is used as the stop solution. As described above, an interconnect material may be corroded due to local cell effect or the like depending upon a material of the surface. In such a case, when the plating is stopped by ultrapure water having a reducing capability, such adverse influences can be avoided.

Thereafter, a plating solution remaining on the surface of the substrate is rinsed (cleaned) with a rinsing liquid such as pure water. Thus, a protective film 9 of a Co—W—P alloy film is formed selectively on surfaces of the interconnects 8 to protect the interconnects 8.

Next, the substrate W after the electroless plating process is transferred to the post-treatment unit 24 by the transfer robot 34. In the post-treatment unit 24, a post-plating treatment is performed to improve the selectivity of the protective film (plated film) 9 formed on the surface of the substrate W and enhance a yield. Specifically, while a physical force, for example, through roll scrubbing cleaning or pencil cleaning, is applied to the surface of the substrate W, a chemical liquid containing one or at least two of a surface-active agent, an organic alkali, and chelating agent is supplied to the surface of the substrate W to completely remove plating residues such as fine metallic particles on the insulating film 2 and improve the selectivity of the plating. The use of such a chemical liquid can improve the selectivity of the electroless plating more efficiently. It is desirable that the surface-active agent be nonionic, that the organic alkali be quaternary ammonium or mines, and that the chelating agent be ethylenediamines.

When such a chemical liquid is used, a chemical liquid remaining on the surface of the substrate W is rinsed (cleaned) with a rinsing liquid such as pure water. Pure water, hydrogen gas dissolved water, or electrolytic cathode water can be used as the rinsing liquid. An interconnect material may be corroded due to local cell effect or the like depending upon a material of the surface as described above. In such a case, by rinsing ultrapure water having a reducing capability, such adverse influences can be avoided.

In addition to cleaning with a physical force, for example, through roll scrubbing cleaning or pencil cleaning, residues on the insulating film 2 may be removed completely by cleaning with a complexing agent, uniformly etching back with an etching liquid, or a proper combination of these methods.

The substrate W after the post-treatment is transferred to the drying unit 26 by the transfer robot 34. In the drying unit 26, a rinsing process is performed as needed. Then, the substrate W is rotated at a high speed to spin-dry the substrate W.

Thus, a series of operations for forming a protective film 9 on exposed surfaces of the embedded interconnects 8 formed in the surface of the substrate W by electroless plating can be performed continuously. Further, since the substrate is finished to a dry state, the substrate can be transferred directly to a subsequent process, and simultaneously degradation of the protective film (plated film) 9 can be prevented before the subsequent process.

It is desirable to control the humidity of an atmosphere around the substrate by using dry air or dry inert gas when the drying process (spin-drying) is performed to bring the substrate W into a dry state. If drying is carried out under a normal atmosphere, then moisture on the substrate is scattered over the atmosphere to increase the humidity. A large amount of moisture is adsorbed on the surface of the atmosphere even though the substrate has been subjected to the drying process. In such a state, adsorbed moisture may raise new problems such as oxidation of the interconnect portions. Further, there may be supposed problems such as generation of watermarks due to misting back in a spin-drier. Thus, when the humidity of an atmosphere is controlled with dry air or dry nitrogen at the time of drying, such adverse influences can be avoided.

The substrate W after the spin-drying is transferred to the heat treatment unit 28 by the transfer robot 34. In the heat treatment unit 28, a heat treatment (annealing) is performed on the substrate W after the post-treatment to reform the protective film 9. It is desirable that the temperature required for reforming the protective film 9 be at least 120° C. in consideration of practical processing time and not more than 450° C. in consideration of heat resistance of materials forming devices. For example, the temperature of the heat treatment (annealing) is 120 to 450° C. Thus, when the heat treatment is performed on the substrate W, it is possible to improve the barrier properties of the protective film (plated film) formed on exposed surfaces of the interconnects and the adhesiveness to the interconnects.

Next, the substrate W after the heat treatment is transferred to the film thickness measurement unit 30, such as an optical measurement unit, an AFM, or an EDX, by the transfer robot 34. In the film thickness measurement unit 30, the film thickness of the protective film 9 formed on the surfaces of the interconnects 8 is measured, and the substrate W after the film thickness measurement is returned to the substrate cassette 10 loaded on the loading/unloading unit 12 by the transfer robot 34.

Measurement results obtained by off-line measurement of the film thickness of the protective film 9 formed on the exposed surfaces of the interconnects 8 are fed back before the electroless plating process to adjust, for example, processing time of plating for a subsequent substrate according to variations of the film thickness. Thus, the film thickness of the protective film 9 formed on the exposed surfaces of the interconnects 8 is measured, and, for example, processing time of plating for a subsequent substrate is adjusted according to variations of the film thickness. Accordingly, the film thickness of the protective film 9 formed on the exposed surfaces of the interconnects 8 can be controlled so as to be constant.

When the protective film 9 is formed selectively on the exposed surfaces of the interconnects 8, planarization of the exposed surfaces of the interconnects 8 should preferably be performed prior to the cleaning process of the exposed surfaces of the interconnects 8 by either one of chemical mechanical polishing, electrochemical polishing, or composite electrochemical polishing. In such a case, a higher level of planarization of the protective film 9 can be achieved.

Next, there will be described below the details of various units provided in the substrate processing apparatus shown in FIG. 2.

The first pre-treatment unit 18 and the second pre-treatment unit 20 use different treatment liquids (chemical liquids) but have the same structure which employs a two-liquid separation system to prevent the different liquids from being mixed with each other. While a peripheral portion of a lower surface of the substrate W, which is a surface to be processed (front face), transferred in a face-down manner is sealed, the substrate W is fixed by pressing a rear face of the substrate.

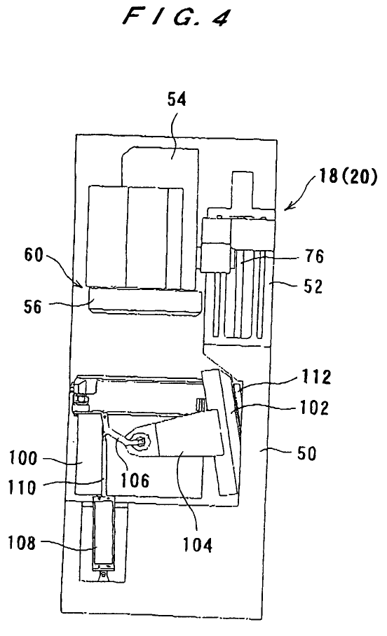

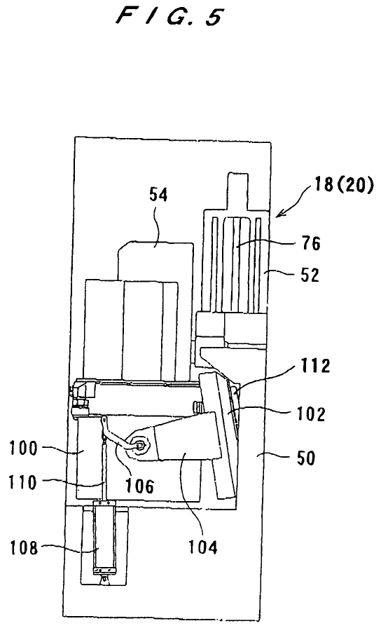

As shown in FIGS. 4 through 7, each of the treatment units 18 and 20 includes a fixed frame 52 mounted on an upper portion of a frame 50, and a movable frame 54 which is vertically movable relative to the fixed frame 52. A processing head 60, which has a bottomed cylindrical housing portion 56 opened downward and a substrate holder 58, is suspended from and supported by the movable frame 54. Specifically, a servomotor 62 for rotating the head is mounted on the movable frame 54, and the housing portion 56 of the processing head 60 is coupled to a lower end of an output shaft (hollow shaft) 64, which extends downward, of the servomotor 62.

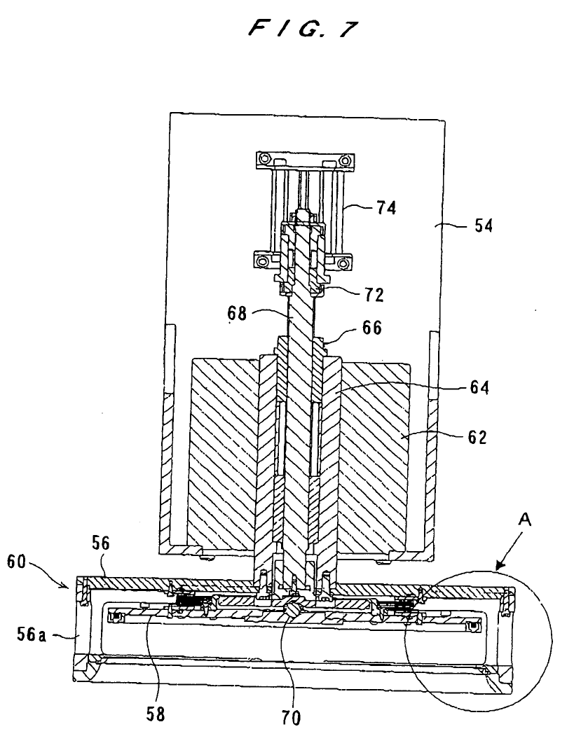

As shown in FIG. 7, a vertical shaft 68, which rotates together with the output shaft 64 via a spline 66, is inserted in the output shaft 64, and the substrate holder 58 of the processing head 60 is coupled to a lower end of the vertical shaft 68 via a ball joint 70. The substrate holder 58 is positioned within the housing portion 56. An upper end of the vertical shaft 68 is coupled via a bearing 72 and a bracket to a cylinder 74 for vertically moving a fixed ring, which is secured to the movable frame 54. Thus, by actuation of the cylinder 74 for vertically movement, the vertical shaft 68 is vertically moved independently of the output shaft 64.

Linear guides 76, which extend vertically and serve to guide vertical movement of the movable frame 54, are mounted to the fixed frame 52, so that the movable frame 54 is moved vertically with a guide of the linear guides 76 by actuation of a cylinder (not shown) for vertically moving the head.

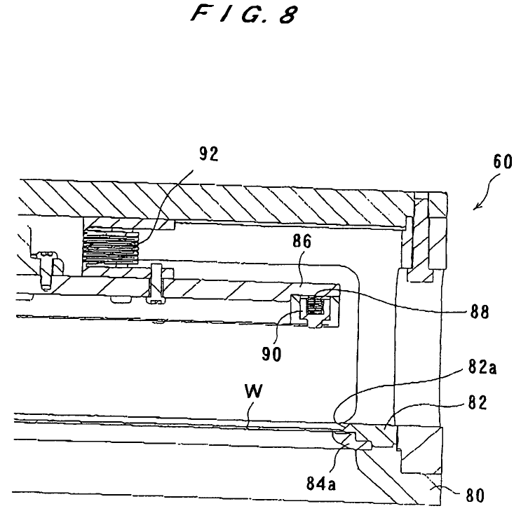

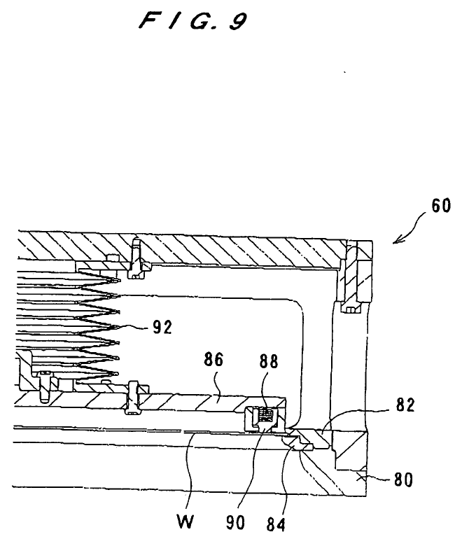

Substrate insertion windows 56a for inserting the substrate W into the housing portion 56 are formed in a circumferential wall of the housing portion 56 of the processing head 60. Further, as shown in FIGS. 8 and 9, a seal ring 84a is disposed in a lower portion of the housing portion 56 of the processing head 60 with an outer peripheral portion of the seal ring 84a being sandwiched between a main frame 80 made of, for example, PEEK and a guide frame 82 made of, for example, polyethylene. The seal ring 84a is brought into abutment against a peripheral portion of a lower surface of the substrate W to seal the peripheral portion.

Meanwhile, a substrate fixing ring 86 is fixed to a peripheral portion of a lower surface of the substrate holder 58. A columnar pusher 90 protrudes downward from a lower surface of the substrate fixing ring 86 by an elastic force of a spring 88 disposed within the substrate fixing ring 86 of the substrate holder 58. Further, a flexible cylindrical bellows plate 92 made of, for example, Teflon (registered trademark) is disposed between an upper surface of the substrate holder 58 and an upper wall of the housing portion 56 to hermetically seal an interior of the housing portion.

When the substrate holder 58 is in a lifted position, a substrate W is inserted through the substrate insertion window 56a into the housing portion 56. The substrate W is then guided by a tapered surface 82a provided in an inner circumferential surface of the guide frame 82, and positioned and placed at a predetermined position on an upper surface of the seal ring 84a. In this state, the substrate holder 58 is lowered so as to bring the pusher 90 of the substrate fixing ring 86 into contact with an upper surface of the substrate W. The substrate holder 58 is farther lowered so as to press the substrate W downward by an elastic force of the spring 88. Thus, the seal ring 84a is brought into contact with a peripheral portion of the front face (lower surface) of the substrate W under pressure to seal the peripheral portion while clamping and holding the substrate W between the housing portion 56 and the substrate holder 58.

When the servomotor 62 for rotating the head is driven in a state such that the substrate W is thus held by the substrate holder 58, the output shaft 64 and the vertical shaft 68 inserted in the output shaft 64 rotate together via the spline 66, so that the substrate holder 58 rotates together with the housing portion 56.

At a position below the processing head 60, there is provided a treatment tank 100 having an outer tank 100a and an inner tank 100b, which has a slightly larger inside diameter than the outside diameter of the processing head 60 and is opened upward. A pair of leg portions 104, which is mounted to a lid 102, is rotatably supported on an outer circumferential portion of the treatment tank 100. Further, a crank 106 is integrally coupled to each leg portion 106, and a free end of the crank 106 is rotatably coupled to a rod 110 of a cylinder 108 for moving the lid. Thus, by actuation of the cylinder 108 for moving the lid, the lid 102 is moved between a treatment position at which the lid 102 covers a top opening portion of the treatment tank 100 and a retracting position beside the treatment tank 100. On the front face (upper surface) of the lid 102, there is provided a nozzle plate 112 having a large number of ejection nozzles 112 for outwardly (upwardly) ejecting a cleaning liquid (rinsing liquid) such as electrolytic ionic water having a reducing capability or ultrapure water from which dissolved oxygen is removed.

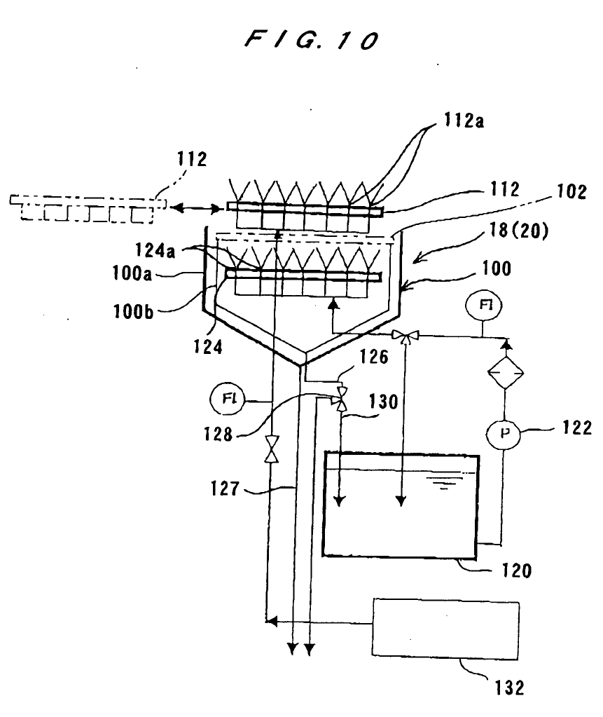

Further, as shown in FIG. 10, a nozzle plate 124 having a plurality of ejection nozzles 124a for upwardly ejecting a chemical liquid supplied from a chemical liquid tank 120 by actuation of a chemical liquid pump 122 is provided in the inner tank 100b of the treatment tank 100 in a manner such that the ejection nozzles 124a are equally distributed over the entire surface of a horizontal cross-section of the inner tank 100b. A drain pipe 126 for draining a chemical liquid (waste liquid) to the outside is connected to the bottom of the inner tank 100b. A three-way valve 128 is provided in the drain pipe 126, and the chemical liquid (waste liquid) is returned to the chemical liquid tank 120 through a return pipe 130 connected to one of outlet ports of the three-way valve 128 so as to reuse the chemical liquid, as needed. Further, in this embodiment, the nozzle plate 112 provided on the front face (upper surface) of the lid 102 is connected to a cleaning liquid supply source 132 for supplying a cleaning liquid (rinsing liquid) such as pure water or ultrapure water from which dissolved oxygen is removed. Furthermore, a drain pipe 127 is connected to a bottom surface of the outer tank 100a.

By lowering the processing head 60 holding the substrate so as to cover the top opening portion of the treatment tank 100 with the processing bead 60 and then ejecting a chemical liquid from the ejection nozzles 124a of the nozzle plate 124 disposed in the inner tank 100b of the treatment tank 100 toward the substrate W, the chemical liquid can be ejected uniformly onto the entire lower surface (surface to be processed) of the substrate W and discharged through the drain pipe 126 to the outside while preventing the chemical liquid from being scattered to the outside. Further, by lifting up the processing head 60, closing the top opening portion of the treatment tank 100 with the lid 102, and then ejecting a cleaning liquid (rinsing liquid) such as ultrapure water from which dissolved oxygen is removed from the ejection nozzles 112a of the nozzle plate 112 disposed on the upper surface of the lid 102 toward the substrate W held in the processing head 60, a rinsing process (cleaning process) for a chemical liquid remaining on the surface of the substrate is performed. Since the cleaning liquid passes through a clearance between the outer tank 100a and the inner tank 100b and is discharged through the drain pipe 127, the cleaning liquid is prevented from flowing into the inner tank 100b and from being mixed with the chemical liquid.

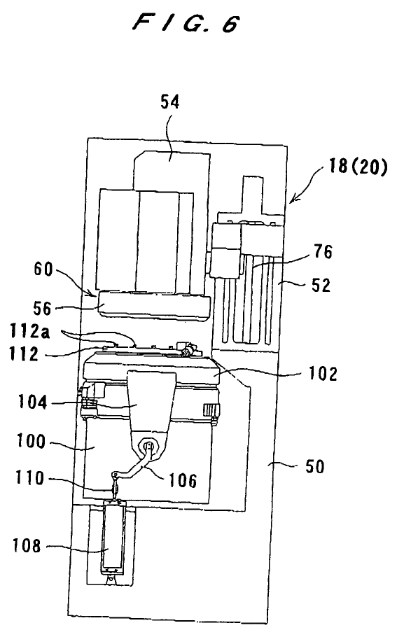

According to the pre-treatment units 18 and 20, the substrate W is inserted into and held in the processing head 60 when the processing head 60 is in the lifted position, as shown in FIG. 4. Thereafter, as shown in FIG. 5, the processing head 60 is lowered to a position at which the processing head 60 covers the top opening portion of the treatment tank 100. While rotating the processing head 60 and thereby rotating the substrate W held in the processing head 60, a chemical liquid is ejected from the ejection nozzles 124a of the nozzle plate 124 disposed in the treatment tank 100 toward the substrate W to thereby eject the chemical liquid uniformly onto the entire surface of the substrate W. The processing head 60 is lifted up and stopped at a predetermined position. As shown in FIG. 6, the lid 102 in the retracting position is moved to a position at which the lid 102 covers the top opening portion of the treatment tank 100. Then, a cleaning liquid (rinsing liquid) such as ultrapure water from which dissolved oxygen is removed is ejected from the ejection nozzles 112a of the nozzle plate 112 disposed on the upper surface of the lid 102 toward the rotating substrate W held in the processing bead 60. Thus, a process of the substrate W with a chemical liquid and a cleaning (rinsing) process of the substrate W with a rinsing liquid can be performed without mixing these two liquids.

The lowermost position of the processing head 60 may be adjusted to adjust a distance between the substrate W held in the processing head 60 and the nozzle plate 124 to thereby adjust a region of the substrate W onto which the chemical liquid is ejected from the ejection nozzles 124a of the nozzle plate 124 and an ejection pressure as desired. Here, when a pre-treatment liquid such as a chemical liquid is circulated and reused, active components are reduced according to progress of the treatment, and the pre-treatment liquid (chemical liquid) is taken out due to attachment of the pretreatment liquid to substrates. Accordingly, it is desirable to provide a pre-treatment liquid management unit (not shown) for analyzing the composition of the pre-treatment liquid and adding insufficient components. Specifically, a chemical liquid used in the cleaning process is mainly composed of acid or alkali. For example, a pH of the chemical liquid can be measured, a decreased content can be replenished from a difference between a preset value and the measured value, and a decreased amount can be replenished using a liquid level meter provided in a chemical liquid reservoir tank. Further, with respect to a catalyst liquid, for example, in a case of an acid palladium solution, the amount of acid can be measured by its pH, the amount of palladium can be measured by a titration method or nephelometry, and a decreased amount can be replenished in the same manner as described above.

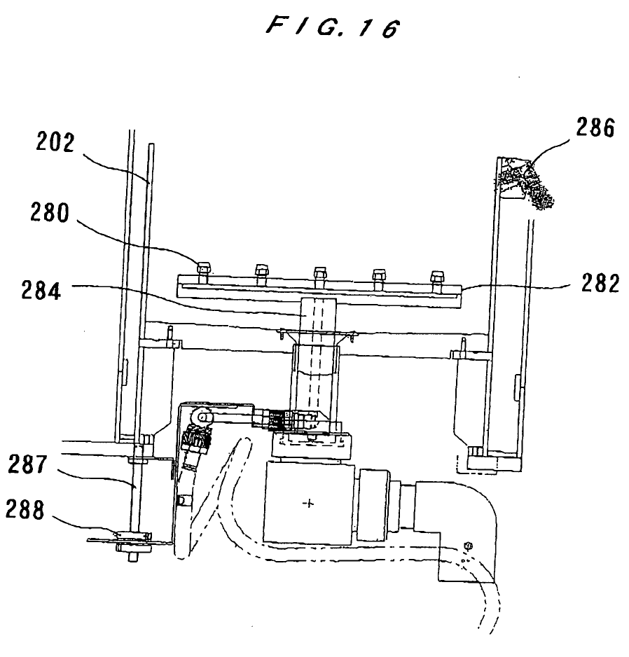

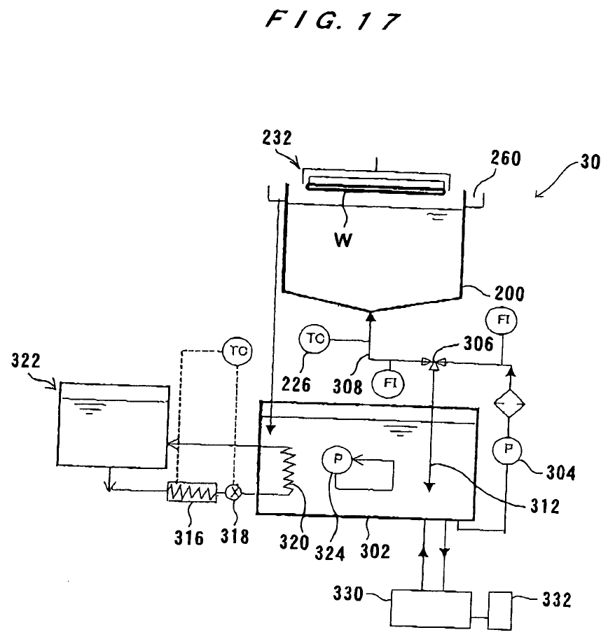

FIGS. 11 through 17 show the electroless plating unit 22. This electroless plating unit 22 has a plating tank 200 (see FIG. 17) and a substrate head 204 disposed above the plating tank 200 for detachably holding a substrate W.

As shown in detail in FIG. 11, the substrate bead 204 has a housing portion 230 and a head portion 232. The head portion 232 is mainly composed of a suction head 234 and a substrate receiver 236 surrounding the suction head 234. A motor 238 for rotating the substrate and cylinders 240 for driving the substrate receiver are housed in the housing portion 230. An upper end of an output shaft (hollow shaft) 242 of the motor 238 for rotating the substrate is coupled to a rotary joint 244, and a lower end of the output shaft is coupled to the suction head 234 of the head portion 232. Rods of the cylinders 240 for driving the substrate receiver are coupled to the substrate receiver 236 of the head portion 232. Stoppers 246 are provided in the housing portion 230 for mechanically limiting upward movement of the substrate receiver 236.

A splined structure is provided between the suction head 234 and the substrate receiver 236. The substrate receiver 236 is vertically moved relative to the suction head 234 by actuation of the cylinders 240 for driving the substrate receiver. When the motor 238 for rotating the substrate is driven to rotate the output shaft 242, the suction head 234 and the substrate receiver 236 are rotated in unison with each other according to the rotation of the output shaft 242.

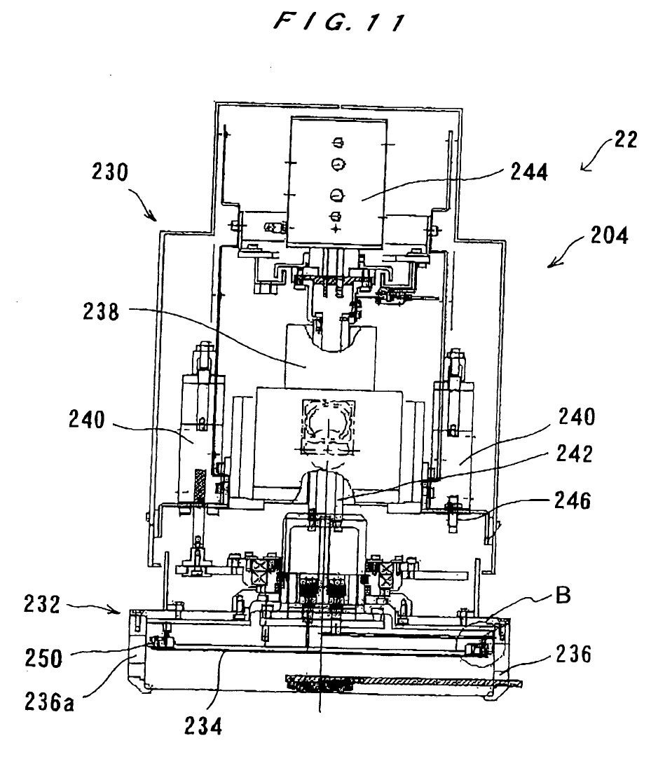

As shown in detail in FIGS. 12 through 14, a suction ring 250 for attracting and holding a substrate W against its lower surface to be sealed is mounted on a lower circumferential edge of the suction head 234 by a presser ring 251. A recess 250a continuously defined in a lower surface of the suction ring 250 in a circumferential direction communicates with a vacuum line 252 extending through the suction head 234 through a communication hole 250b defined in the suction ring 250. By evacuating the recess 250a, the substrate W is attracted and held. Thus, the substrate W is attracted and held under vacuum along a (radially) narrow circumferential area. Accordingly, it is possible to minimize any adverse effects (flexing or the like) caused by the vacuum on the substrate W. Further, when the suction ring 250 is immersed in the plating solution (treatment liquid), all portions of the substrate W including not only the front face (lower surface) of the substrate W, but also its circumferential edge can be immersed in the plating solution. The substrate W is released by supplying N₂ into the vacuum line 252.

Meanwhile, the substrate receiver 236 is in the form of a bottomed cylinder opened downward. Substrate insertion windows 236a for inserting the substrate W into the substrate receiver 236 are defined in a circumferential wall of the substrate receiver 236. A disk-like ledge 254 projecting inward is provided at a lower end of the substrate receiver 236. A protrusion 256 having an inner tapered surface 256a for guiding the substrate W is provided on an upper portion of the ledge 254.

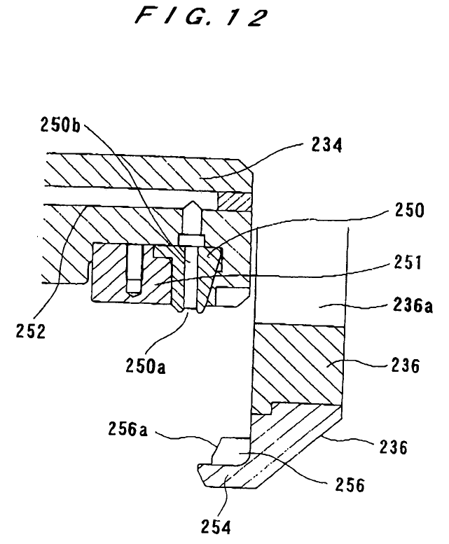

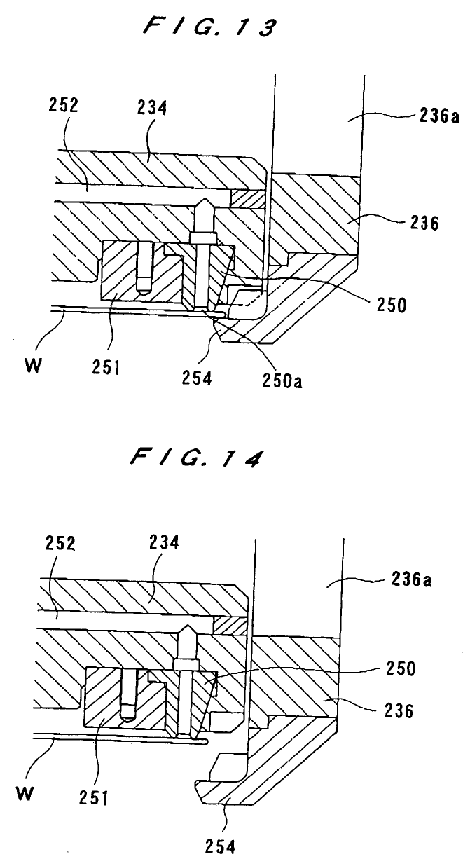

As shown in FIG. 12, when the substrate receiver 236 is in a lowered position, the substrate W is inserted through the substrate insertion window 236a into the substrate receiver 236. The substrate W is then guided by the tapered surface 256a of the protrusion 256 and positioned and placed at a predetermined position on an upper surface of the ledge 254 of the substrate receiver 236. In this state, as shown in FIG. 13, the substrate receiver 236 is lifted up so as to bring the upper surface of the substrate W placed on the ledge 254 of the substrate receiver 236 into abutment against the suction ring 250 of the suction head 234. Then, the recess 250a in the vacuum ring 250 is evacuated through the vacuum line 252 to attract and hold the substrate W while sealing the upper peripheral edge surface of the substrate W against the lower surface of the suction ring 250. For performing a plating process, as shown in FIG. 14, the substrate receiver 236 is lowered several millimeters to space the substrate W from the ledge 254 so that the substrate W is attracted and held only by the suction ring 250. Thus, it is possible to prevent the front face (lower surface) of the peripheral edge portion of the substrate W from not being plated because of the presence of the ledge 254.

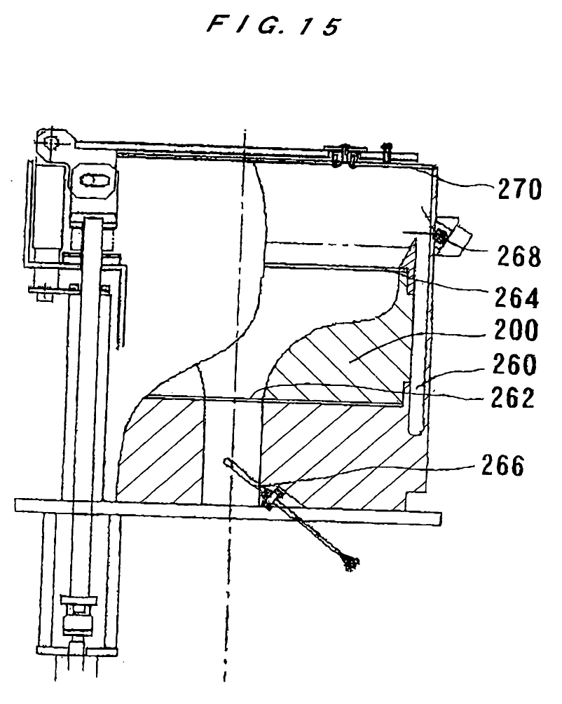

FIG. 15 shows the details of the plating tank 200. The plating tank 200 is connected at the bottom to a plating solution supply pipe 308 (see FIG. 17) and is provided in the peripheral wall with a plating solution recovery gutter 260. In the plating tank 200, there are disposed two current plates 262 and 264 for stabilizing the flow of a plating solution flowing upward. A thermometer 266 for measuring the temperature of the plating solution to be introduced into the plating tank 200 is disposed at the bottom of the plating tank 200. Further, on the outer surface of the peripheral wall of the plating tank 200 and at a position slightly higher than the liquid level of the plating solution held in the plating tank 200, there is provided an ejection nozzle 268 for ejecting a stop solution which is a neutral liquid having a pH of 6 to 7.5, for example, pure water, slightly upward with respect to a diametrical direction in the plating tank 200. After the plating, the substrate W held in the head portion 232 is lifted up and stopped at a position slightly above the liquid level of the plating solution. In this state, pure water (stop solution) is ejected from the ejection nozzle 268 toward the substrate W to cool the substrate W immediately, thereby preventing progress of plating by the plating solution remaining on the substrate W.

Further, at a top opening portion of the plating tank 200, there is provided a plating tank cover 270 which closes the top opening portion of the plating tank 200 so as to prevent unnecessary evaporation of the plating solution from the plating tank 200 when the plating process is not performed, such as at the time of idling.

As shown in FIG. 17, the plating tank 200 is connected at the bottom to a plating solution supply pipe 308 extending from a plating solution reservoir tank 302 and having a plating solution supply pump 304 and a three-way valve 306. Thus, during a plating process, a plating solution is supplied from the bottom of the plating tank 200 into the plating tank 200, and an overflowing plating solution is recovered to the plating solution reservoir tank 302 by the plating solution recovery gutter 260. Thus, the plating solution can be circulated. A plating solution return pipe 312 for returning the plating solution to the plating solution reservoir tank 302 is connected to one of ports of the three-way valve 306. Accordingly, the plating solution can be circulated even at the time of a standby for plating. Thus, a plating solution circulating system is constructed. As described above, the plating solution in the plating solution reservoir tank 302 is continuously circulated through the plating solution circulating system to thus reduce a rate of lowering the concentration of the plating solution and to increase the number of the substrates W which can be processed, as compared to a case where a plating solution is simply stored.

Particularly, in this embodiment, by controlling the plating solution supply pump 304, the flow rate of the plating solution circulated at the time of a standby of plating or a plating process can be set individually. Specifically, the amount of plating solution circulated at the time of the standby of plating is set to be in a range of 2 to 20 L/min, for example, and the amount of plating solution circulated at the time of the plating process is set to be in a range of 0 to 10 L/min, for example. Thus, a large amount of plating solution circulated at the time of the standby of plating can be ensured so as to maintain the temperature of a plating bath in a cell to be constant, and the amount of plating solution circulated at the time of the plating process is reduced so as to deposit a protective film (plated film) having a more uniform thickness.

The thermometer 266 provided in the vicinity of the bottom of the plating tank 200 measures the temperature of the plating solution to be introduced into the plating tank 200 and controls a heater 316 and a flow meter 318 described below based on the measurement results.

Specifically, in this embodiment, there are provided a heating device 322 for heating the plating solution indirectly by a heat exchanger 320 provided in the plating solution in the plating solution reservoir tank 302 and employing, as a heating medium, water that has been increased in temperature by a separate heater 316 and passed through the flow meter 318, and a stirring pump 324 for circulating the plating solution in the plating solution reservoir tank 302 to stir the plating solution. This is because the unit should be arranged so that the unit can cope with a case where the plating solution is used at a high temperature (about 80° C.). This method can prevent an extremely delicate plating solution from being mixed with foreign matter or the like, unlike an in-line heating method.

FIG. 16 shows the details of a cleaning tank 202 provided beside the plating tank 200. At the bottom of the cleaning tank 202, there is provided a nozzle plate 282 onto which a plurality of ejection nozzles 280 for ejecting a rinsing liquid such as pure water upward are attached. The nozzle plate 282 is coupled to an upper end of a nozzle vertical shaft 284. The nozzle vertical shaft 284 can be moved vertically by changing positions of engagement between a nozzle position adjustment screw 287 and a nut 288 engaging the screw 287 so as to optimize a distance between the ejection nozzles 280 and the substrate W disposed above the ejection nozzles 280.

Further, on the outer surface of the peripheral wall of the cleaning tank 202 and at a position higher than the ejection nozzles 280, there is provided a head cleaning nozzle 286 for ejecting a cleaning liquid such as pure water slightly downward with respect to a diametric direction in the cleaning tank 202 to blow the cleaning liquid to at least a portion of the head portion 232 of the substrate head 204 which is brought into contact with the plating solution.

In the cleaning tank 202, the substrate W held in the head portion 232 of the substrate head 204 is located at a predetermined position in the cleaning tank 202. A cleaning liquid (rinsing liquid) such as pure water is ejected from the ejection nozzles 280 to clean (rinse) the substrate W. At that time, a cleaning liquid such as pure water is ejected from the head cleaning nozzle 286 to clean, with the cleaning liquid, at least a portion of the head portion 232 of the substrate head 204 which is brought into contact with the plating solution, thereby preventing a deposit from accumulating on a portion which is immersed in the plating solution.

According to this electroless plating unit 22, when the substrate head 204 is in a lifted position, the substrate W is attracted to and held in the head portion 232 of the substrate head 204 as described above, while the plating solution in the plating tank 200 is circulated.

When a plating process is performed, the plating tank cover 270 of the plating tank 200 is opened, and the substrate head 204 is lowered while being rotated. Thus, the substrate W held in the head portion 232 is immersed in the plating solution in the plating tank 200.

After immersing the substrate W in the plating solution for a predetermined period of time, the substrate head 204 is raised to lift the substrate W from the plating solution in the plating tank 200 and, as needed, pure water (stop solution) is ejected from the ejection nozzles 268 toward the substrate W to immediately cool the substrate W, as described above. The substrate head 204 is further raised to lift the substrate W to a position above the plating tank 200, and the rotation of the substrate head 204 is stopped.

Next, while the substrate W is attracted to and held in the head portion 232 of the substrate head 204, the substrate head 204 is moved to a position right above the cleaning tank 202. While the substrate head 204 is rotated, the substrate head 204 is lowered to a predetermined position in the cleaning tank 202. A cleaning liquid (rinsing liquid) such as pure water is ejected from the ejection nozzles 280 to clean (rinse) the substrate W. At that time, a cleaning liquid such as pure water is ejected from the head cleaning nozzle 286 to clean at least a portion the head portion 232 of the substrate head 204 which is brought into contact with the plating solution.

After completion of cleaning of the substrate W, the rotation of the substrate head 204 is stopped, and the substrate head 204 is raised to lift the substrate W to a position above the cleaning tank 202. Further, the substrate head 204 is moved to a transfer position between the transfer robot 34 and the substrate head 204. Then, the substrate W is delivered to the transfer robot 34 and is transferred to a subsequent process by the transfer robot 16.

As shown in FIG. 17, the electrolytic plating unit 22 is provided with a plating solution management unit 330 for measuring the amount of plating solution held in the electroless plating unit 22, analyzing the composition of the plating solution by an absorptiometric method, a titration method, an electrochemical measurement, or the like, and replenishing insufficient components in the plating solution. In the plating solution management unit 330, signals indicative of the analysis results are processed to replenish insufficient components from a replenishment tank, which is not shown, to the plating solution reservoir tank 302 using a metering pump or the like, thereby controlling the amount of the plating solution and the composition of the plating solution. Thus, thin film plating can be achieved with high reproducibility.

The plating solution management unit 330 has a dissolved oxygen concentration meter 332 for measuring dissolved oxygen in the plating solution held in the electroless plating unit 22, for example, by an electrochemical method. The plating solution management unit 330 can control the dissolved oxygen concentration of the plating solution so as to be constant, for example, by deaeration, nitrogen blowing, or other methods, based on indication of the dissolved oxygen concentration meter 332. Thus, the dissolved oxygen concentration in the plating solution can be controlled at a constant value, and the plating reaction can be achieved with high reproducibility.

When the plating solution is used repeatedly, a specific component may be accumulated by external introduction or decomposition of the plating solution to cause degraded reproducibility of the plating or a degraded film. By adding a mechanism for selectively removing such a specific component, it is possible to prolong the lifetime of the liquid and improve the reproducibility.

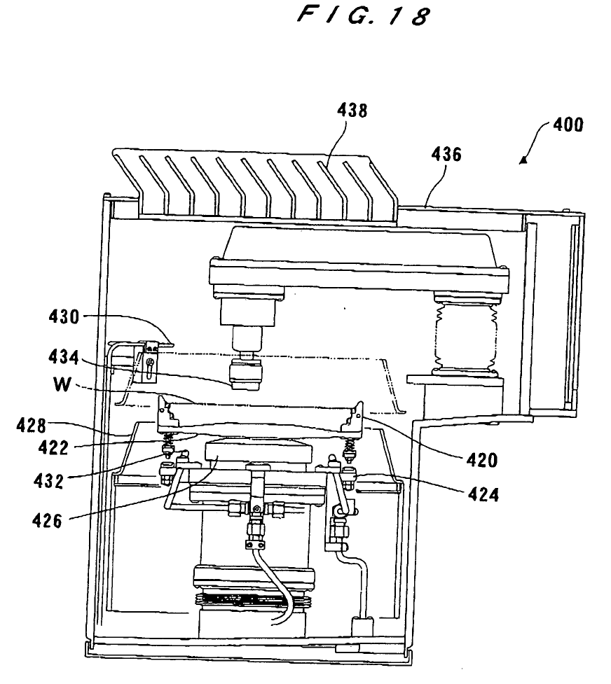

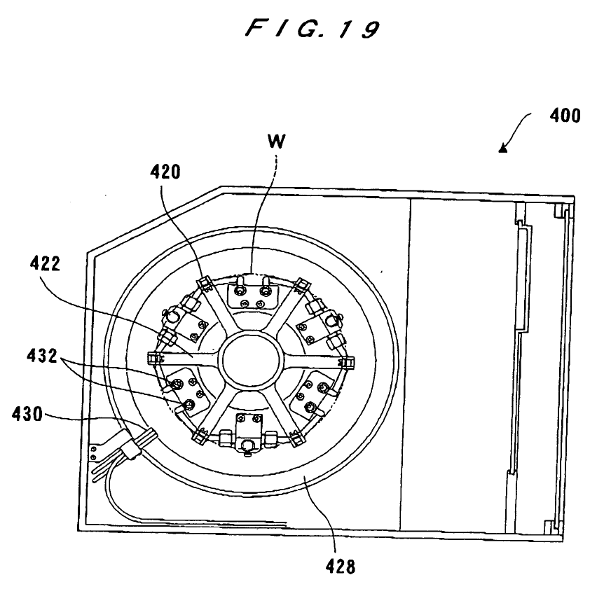

FIGS. 18 and 19 show a post-treatment and drying unit 400 into which the post-treatment unit 24 and the drying unit 26 shown in FIG. 2 are combined to continuously perform a post-treatment and a drying process of a substrate. Specifically, the post-treatment and drying unit 400 first performs chemical cleaning (post-treatment) and pure water cleaning (rinsing) and then completely dries the substrate W after the cleaning by spindle rotation. The post-treatment and drying unit 400 has a substrate stage 422 having a clamp mechanism 420 for clamping an edge portion of the substrate W, and a vertically movable plate 424 for mounting and removing a substrate which opens and closes the clamp mechanism 420.

The substrate stage 422 is coupled to an upper end of a spindle 426 which is rotated at a high speed by actuation of a motor (not shown) for rotating the spindle. Further, a cleaning cup 428 for preventing a treatment liquid from being scattered is disposed around the substrate W held by the clamp mechanism 420. The cleaning cup 428 is vertically moved by actuation of a cylinder, which is not shown.

Further, the post-treatment and drying unit 400 has a chemical liquid nozzle 430 for supplying a treatment liquid to the surface of the substrate W held by the clamp mechanism 420, a plurality of pure water nozzles 432 for supplying pure water to a rear face of the substrate W, and a rotatable pencil-type cleaning sponge 434 disposed above the substrate W held by the clamp mechanism 420. The cleaning sponge 434 is attached to a free end of a swingable arm 436 which is swingable in a horizontal direction. Clean air introduction ports 438 for introducing clean air into the unit are provided at an upper portion of the post-treatment and drying unit 400.

With the post-treatment and drying unit 400 having the above structure, the substrate W is held and rotated by the clamp mechanism 420. While the swingable arm 436 is swung, a treatment liquid is supplied from the chemical liquid nozzle 430 to the cleaning sponge 434, and the surface of the substrate W is rubbed with the cleaning sponge 434, thereby performing post-treatment of the surface of the substrate W. Further, pure water is supplied to the rear face of the substrate W from the pure water nozzles 432, and the rear face of the substrate W is simultaneously cleaned (rinsed) by the pure water ejected from the pure water nozzles 432. The cleaned substrate W is spin-dried by rotating the spindle 426 at a high speed.

It is desirable that the drying unit have a dry air unit, which is not shown, for supplying dry air into the dry unit, and that dry air be supplied into the drying unit when the substrate is spin-dried. In this case, it is possible to dry the substrate thoroughly and prevent oxidation of interconnect portions due to adsorbed moisture or Generation of watermarks due to misting back.

When hydrogen gas dissolved water or electrolytic cathode water is used as a rinsing liquid, each unit may be provided with a device for dissolving a hydrogen gas in ultrapure water or a device for electrolyzing ultrapure water. Hydrogen gas dissolved water or electrolytic cathode water may be supplied from these devices to the substrate.

Here, in this embodiment, a Co—W—P alloy film is used as a protective film 9. However, a protective film made of Co—P, Ni—P, or Ni—W—P may be used. Further, copper is used as an interconnect material. However, copper alloy, silver, silver alloy, gold, gold alloy, or the like may be used as an interconnect material, instead of copper.

Further, in this embodiment, a protective film 9 is formed on surfaces of embedded interconnects 8 formed in a substrate. However, a conductive film (protective film) having a function to prevent diffusion of the interconnect material into an interlayer dielectric film may be formed on bottom surfaces and side surfaces of the embedded interconnects 8 in the same manner as described above.

High accuracy is required in film thickness, film quality, and selectivity when the aforementioned protective film (plated film) 9 is formed. Accordingly, it is necessary to control periods of time between respective process steps. In order to meet such a demand, it is effective to perform all of the process steps in the same apparatus. The substrate processing apparatus according to the present invention can meet such a demand.

A chemical liquid or a plating solution remaining on a surface of the substrate after a chemical liquid process or a plating process would have an adverse influence on the within wafer uniformity of the protective film (plated film) or deposition conditions such as electric characteristics of interconnects. Accordingly, a chemical liquid process and a pure water rinsing process are performed in the same unit to quickly remove a chemical liquid or a plating solution remaining on the surface of the substrate. Thus, a footprint of the apparatus can be reduced, and semiconductor devices or the like can be manufactured with a high yield.

Here, when a chemical liquid process or a rinsing process employing an ejection method is performed, a fresh liquid can continuously be supplied to the surface of the substrate uniformly in a dispersed manner, thereby reducing a period of processing time. By adjusting positions of the ejection points, uniformity of the process of the protective film over the surface of the substrate can readily be improved. For example, if a mild process is required for the surface of the substrate, an immersion method may be employed as a matter of course.

Because the ejection nozzles have a limitation on ejection angles of a liquid, one ejection nozzle can cover only a limited area. If an ejection distance is so short, then more ejection nozzles are required to eject a chemical liquid or the like to an overall surface of the substrate. If an ejection distance is so long, then an oversized pressure device is required, so that the height of the entire plating device is increased. Accordingly, it is desirable that the number of ejection nozzles used in one process be, for example, 1 to 25, and that distances from the ejection nozzles to the substrate be, for example, about 10 to 150 mm. Further, it is desirable that the flow rate of the chemical liquid or the like ejected from one ejection nozzle be 0.2 to 1.2 L/min, and that the ejection pressure be about 10 to 100 kPa.

As described above, according to the present invention, a series of operations for forming a protective film on bottom surfaces and side surfaces or exposed surfaces of embedded interconnects formed in a surface of a substrate by electroless plating can be performed continuously. Further, since the substrate is finished to a dry state, the substrate can be transferred directly to a subsequent process, and simultaneously degradation of the protective film (plated film) can be prevented before the subsequent process. Thus, the reproducibility can be achieved over a surface of a substrate such as a semiconductor wafer and between substrates, and semiconductor devices or the like can be manufactured with a high yield.

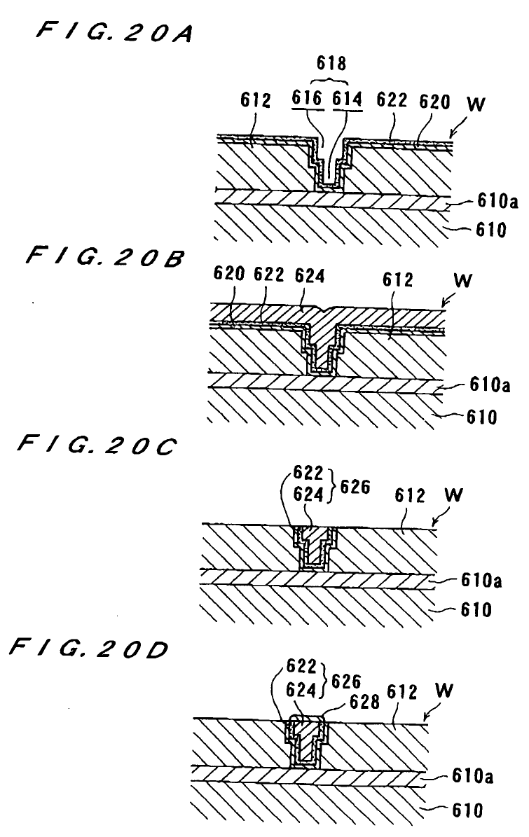

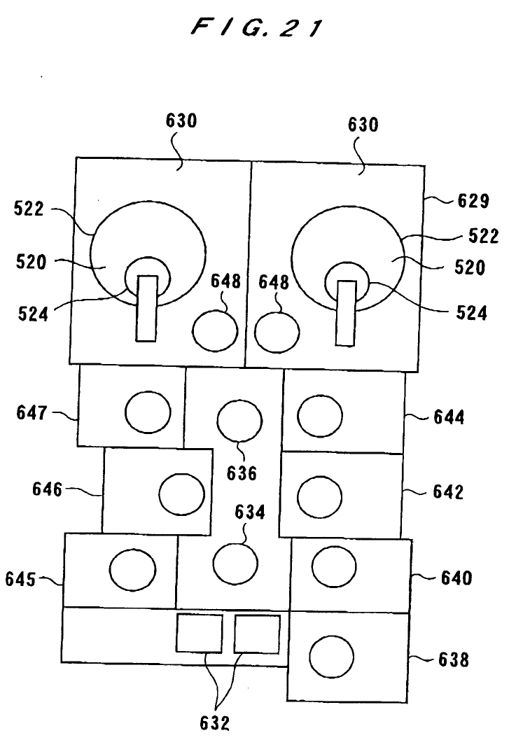

FIGS. 20A through 20D show an example of forming copper interconnects in a semiconductor device in a processing order. As shown in FIG. 20A, an insulating film (interlayer dielectric film) 612 of, for example, SiO₂ is deposited on a conductive layer 610a on a semiconductor base 610 having semiconductor elements formed therein. Interconnect recesses 618 such as contact holes 614 or trenches 616 are formed in the insulating film 612 by performing a lithography/etching technique. Thereafter, a barrier layer 620 of Ta, TaN, or the like is formed on the insulating film, and a seed layer 622 as an electric supply layer for electroplating is formed on the barrier layer by sputtering or the like. A substrate W thus processed is prepared.

Then, as shown in FIG. 20B, copper plating is conducted on a surface of the semiconductor substrate W to fill the contact holes 614 and the trenches 616 of the semiconductor substrate W with copper as an interconnect material and, at the same time, to deposit a copper layer 624 on the insulating film 612. Thereafter, the copper layer 624 and the barrier layer 620 on the insulating film 612 are removed, for example, by chemical mechanical polishing (CMP) using slurry or the like so that a surface of the copper layer 624 filled in the interconnect recesses 618 such as contact holes 614 or trenches 616 is substantially on the same plane as a surface of the insulating film 612. Thus, interconnects (copper interconnects) 626 composed of the seed layer 622 and the copper layer 624, as shown in FIG. 20C, are formed in the insulating film 612.

Next, the surface of the substrate in which the interconnects 626 are thus formed is cleaned and dried. After a pre-plating process such as a catalytic process, for example, to apply a Pd catalyst, as shown in FIG. 20D, electroless plating is carried out on the surface of the substrate W to form a protective film 628 of, for example, a Co—W—P alloy film selectively on externally exposed surfaces of the interconnects 626 so as to protect the interconnects 626.

FIG. 21 is a horizontal arrangement view of an example of a substrate processing apparatus (manufacturing apparatus for semiconductor devices). The substrate processing apparatus has a pair of polishing units 630 laterally opposed to each other, which is disposed at one end of a space on a substantially rectangular floor in a housing 629, and a pair of loading/unloading sections each for placing thereon a substrate cassette 632 housing substrates W such as semiconductor wafers, which is disposed at the other end of the space. A first transfer robot 634 and a second transfer robot 636 are disposed on a line interconnecting the polishing units 630 and the loading/unloading sections. Further, on one side of a transfer line, there are disposed a film thickness measurement unit 638 having a reversing machine, a first plating unit 640 for filling copper, and a first pre-treatment unit 642 and a second pre-treatment unit 644 for performing a pre-plating process of the substrate. On the other side of the transfer line, there are disposed a rinsing and drying unit 645, a second plating unit 646 for forming a protective film, a cleaning unit 647 having a roll sponge. Vertically movable pushers 648 are provided on the transfer line sides of the polishing units 630 for transferring the substrate W between the pushers and the polishing units 630.

Here, in this embodiment, each of the polishing units 630 comprises a CMP device including a polishing table 522 having a polishing cloth (polishing pad) 520, which forms a polishing surface, attached to an upper surface thereof, and a top ring 524 for holding a substrate W in a state such that a surface of the substrate to be polished faces the polishing table 522.

Further, the housing 629 is shaded so as to perform the following processes in a shaded state within the housing 629, i.e., in a state such that light such as illumination light is not applied to the interconnects. Since light is prevented from being applied to the interconnects, the interconnects are prevented from being corroded due to photoelectric potentials produced when light is applied to the interconnects of, for example, copper.

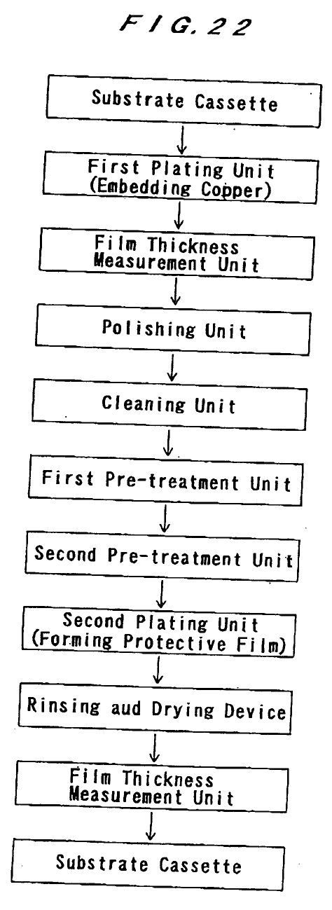

Next, a series of plating operations by the substrate processing apparatus will be described with reference to FIGS. 20 and 21, further to FIG. 22. As shown in FIGS. 20A through 20D, there will be described an example in which a protective film (cap material) 628 of a Co—W—P alloy film is selectively formed to protect interconnects 626.

First, each substrate W hating interconnect recesses 618 and a seed layer 622 formed on a surface thereof as shown in FIG. 20A is taken out from the substrate cassette 632 by the first transfer robot 634 and transferred into the first plating unit 640. In the first plating unit 640, as shown in FIG. 20B, a copper layer 624 is deposited on the surface of the substrate W to fill the recesses with copper. The copper layer 624 is formed by performing a hydrophilic treatment on the surface of the substrate W and then copper plating the substrate. After the copper layer 624 is formed, rinsing or cleaning is conducted in the first plating unit 640. If there is plenty of time to spare, drying may be conducted.

The substrate W in which copper has been filled is transferred to the film thickness measurement unit 638, where the film thickness of the copper layer 624 is measured. The substrate W is reversed by the reversing machine, as needed, and then transferred to the pusher 648 of the polishing unit 630 by the first transfer robot 634 and the second transfer robot 636.

In the polishing unit 630, the substrate W above the pusher 648 is attracted to and held by the top ring 524 and moved to above the polishing table 522. Then, the top ring 524 is lowered to press a surface of the substrate W to be polished against the polishing cloth 520 on the rotating polishing table 522 under a predetermined pressure. At that time, a polishing liquid (slurry) is supplied to polish the substrate. With regard to polishing conditions, when a copper layer 624 formed on the substrate W is polished, slurry for copper polishing (polishing liquid) is used. It has been known that in a case where a surface of a substrate has irregularities, it is effective to conduct polishing under a lower pressing force at a relatively high speed. However, in such a case, a processing speed itself is lowered. Accordingly, for example, multistage polishing may be conducted by processing to a certain degree under conditions that a pressing force of the top ring is 40 kPa and a rotational speed of the top ring is 70 min⁻¹ for a predetermined period of time, and then polishing under conditions that a pressing force of the top ring is 20 kPa and a rotational speed of the top ring is 50 min⁻¹. In such a case, efficient planarization can be achieved as a whole.

For example, polishing is completed when a monitor to inspect a finish of the substrate detects an endpoint. The substrate W that has been completely polished is returned to the pusher 648 by the top ring 524 and cleaned by pure water spray. Thus, as shown in FIG. 20C, interconnects (copper interconnects) 626 composed of a seed layer 622 and a copper layer 624 are formed in the insulating film 612.

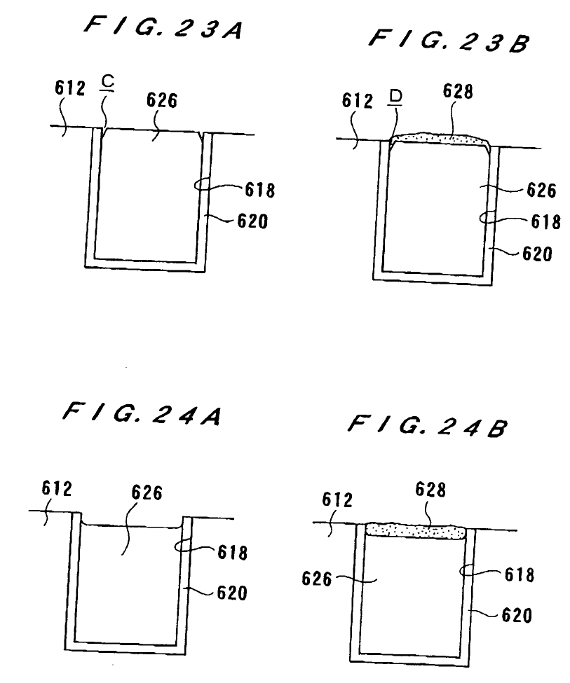

At that time, it is desirable to use a polishing liquid (slurry) such that a surface potential when the barrier layer 620 is immersed therein is nobler than a surface potential when the interconnects 626 are immersed therein. With a polishing liquid such that a surface potential when the barrier layer 620 is immersed therein is nobler than a surface potential when the interconnects 626 are immersed therein, it is possible to prevent generation of V-shaped corrosion (recesses) C (see FIG. 23A) at an interface between the barrier layer 620 and the interconnects 626 when the copper layer 624 on the substrate W is polished by CMP so as to expose surfaces of embedded interconnects 626. Accordingly, it is possible to prevent generation of defects D (see FIG. 23B) caused by the aforementioned V-shaped corrosion at the interface between the barrier layer 620 and the interconnects 626 when a protective film 628 is formed selectively on surfaces of the interconnects 626 by electroless plating.

The CMP may be performed with a polishing liquid such that a surface potential when the barrier layer 620 is immersed therein is less noble than a surface potential when the interconnects 626 are immersed therein, and the cleaning process of the pre-plating process may be performed with a treatment liquid such that a surface potential when the barrier layer 620 is immersed therein is nobler than a surface potential when the interconnects 626 are immersed therein.

As described above, when the copper layer 624 of an interconnect material on the substrate W is polished and planarized by CMP using a polishing liquid (slurry) such that a surface potential when the barrier layer 620 is immersed therein is less noble than a surface potential when the interconnects 626 are immersed therein, then V-shaped corrosion (recesses) C may be generated at an interface between the barrier layer 620 and the interconnects 626 as shown in FIG. 23A. If a protective film 628 is formed selectively on the interconnects 626 with the V-shaped corrosion C by electroless plating as described below, then plating is not carried out due to the fact that the polishing liquid or the cleaning liquid remains in the V-shaped recesses C, thereby causing plating defects D as shown in FIG. 23B. Accordingly, before the plating, the substrate is subjected to a pre-plating process (cleaning) with a treatment liquid such that a surface potential when the barrier layer 620 is immersed therein is nobler than a surface potential when the interconnects 626 are immersed therein. Thus, the interconnects 626 are slightly etched to eliminate the V-shaped recesses C so that a polishing liquid or a cleaning liquid does not remain on the substrate. As shown in FIG. 24B, defects of the protective film 628 are prevented from being generated due to the presence of the V-shaped corrosion (recesses) C.

Next, the polished substrate W is transferred to the cleaning unit 647 by the second transfer robot 636, and the surface of the substrate is cleaned therein with a roll sponge or the like.

Then, the cleaned substrate is transferred to the first pre-treatment unit 42 by the second transfer robot 36. In the first pre-treatment unit 42, the substrate W is held in a face-down manner, and a cleaning process (chemical liquid cleaning) is performed as a pre-plating process on the surface of the substrate W. This process is substantially the same as the aforementioned process in the first pre-treatment unit 18 as shown in FIG. 2, and will not be described repetitively.

The surface of the substrate W after the cleaning is cleaned (rinsed) with a cleaning liquid (rinsing liquid) to prevent a chemical liquid used for cleaning from remaining on the surface of the substrate W and inhibiting a subsequent activation process. Ultrapure water is generally used as a cleaning liquid. However, depending upon a material of the seed layer 622, even if ultrapure water is used, interconnects 626 may be corroded due to local cell effect or the like as in the aforementioned case shown in FIG. 23A. Accordingly, it is desirable to use a cleaning liquid (rinsing liquid) such that a potential difference between exposed surfaces of the interconnects 626 and an exposed surface of the barrier layer 620 is not more than 200 mV when the substrate W is immersed therein. Thus, even with any combination of interconnects (material) and a barrier layer (material), it is possible to prevent the interconnects from being selectively corroded during the substrate cleaning process after the pre-plating treatment, and to prevent an increase of the interconnect resistance or defects of the interconnects.

Such a cleaning liquid may include ultrapure water from which dissolved oxygen is removed. Specifically, it is desirable to use a cleaning liquid that is inert to both of the barrier layer (material) and the interconnects (material) and produces substantially no potential differences between the barrier layer and the interconnects when the barrier layer and the interconnects are immersed simultaneously therein. This requirement can be met when ultrapure water from which dissolved oxygen is sufficiently removed is used.

Such a cleaning liquid may also include ultrapure water in which hydrogen gas is dissolved. By dissolving hydrogen gas in ultrapure water, it is possible to lower potentials to both of the barrier layer (material) and the interconnects (material) and to reliably reduce a potential difference produced between the barrier layer and the interconnects when the barrier layer and the interconnects are immersed simultaneously in the ultrapure water. Methods of dissolving hydrogen gas include (1) a method of dissolving hydrogen gas via a gas dissolving membrane in ultrapure water, and (2) a method of electrolyzing ultrapure water to produce hydrogen gas and dissolving the hydrogen gas directly in ultrapure water. Both of the methods can be employed. During a manufacturing process of ultrapure water, ultraviolet irradiation may be performed to decompose and remove dissolved organic matter, and the dissolved hydrogen concentration may be increased according to the decomposition reaction. The present invention also includes such possibility.

When the copper layer 624 as an interconnect material on the substrate W is polished and planarized by CMP using a polishing liquid (slurry) such that a surface potential when the barrier layer 620 is immersed therein is less noble than a surface potential when the interconnects 626 are immersed therein, as described above, the substrate is cleaned with the cleaning liquid of a treatment liquid such that a surface potential when the barrier layer 620 is immersed therein is nobler than a surface potential when the interconnects 626 are immersed therein.

Next, the substrate W after the cleaning process and the washing process is transferred to the second pre-treatment unit 42 by the second transfer robot 34. In the second pre-treatment unit 42, the substrate W is held in a face-down manner, and a catalyst application process is performed on the surface of the substrate. This process is substantially the same as the aforementioned process in the second pre-treatment unit 20 as shown in FIG. 2, and will not be described repetitively.

Then, in order to improve the selectivity, the substrate is cleaned (rinsed) with a cleaning liquid (rinsing liquid) to remove Pd residues on the seed layer 622 and the interconnects 626. As in the case of the aforementioned cleaning process, it is desirable to use a cleaning liquid (rinsing liquid) such that a potential difference between exposed surfaces of the interconnects 626 and an exposed surface of the barrier layer 620 is not more than 200 mV when the substrate W is immersed therein, e.g., ultrapure water from which dissolved oxygen is removed, or ultrapure water in which hydrogen gas is dissolved. Thus, it is possible to prevent the interconnects 626 from being selectively corroded.

Then, the substrate W to which the catalyst has been applied and which has been subjected to the rinsing process is transferred to the second plating unit 646 of, for example, an electroless plating device by the second transfer robot 636 In the second plating unit 646, the substrate W is held in a face-down manner, and an electroless plating process is performed on the surface of the substrate W. This process is substantially the same as the aforementioned process in the electroless plating unit 22 as shown in FIG. 2, and will not be described repetitively.

Then, after the substrate W is lifted up from the plating solution, a stop solution of a neutral liquid having a pH of 6 to 7.5 is brought into contact with the surface of the substrate W to stop the electroless plating process. Thereafter, a plating solution remaining on the surface of the substrate is rinsed (cleaned) with a rinsing liquid such as pure water. Thus, a protective film 628 of a Co—W—P alloy film is formed selectively on surfaces of the interconnects 626 to protect the interconnects 626.

Next, the substrate W after the electroless plating process is transferred to the cleaning unit 647 by the second transfer robot 636. In the cleaning unit 647, a post-plating treatment is performed to improve the selectivity of the protective film (plated film) 628 formed on the surface of the substrate W and enhance a yield. This process is substantially the same as the aforementioned process in the post-treatment unit 24 as shown in FIG. 2, and will not be described repetitively.

Then, the substrate W after the post-treatment is transferred to the rinsing and drying unit 645 by the transfer robot 634. In the rinsing and drying unit 645, a rinsing process is performed, and the substrate W is then rotated at a high speed to spin-dry the substrate W.

Thus, a series of operations for forming a protective film 628 on exposed surfaces of the embedded interconnects 626 formed in the surface of the substrate W by electroless plating can be performed continuously. Further, since the substrate is finished to a dry state, the substrate can be transferred directly to a subsequent process, and simultaneously degradation of the protective film (plated film) 628 can be prevented before the subsequent process.

The spin-dried substrate W is transferred to the film thickness measurement unit 638, such as an optical measurement unit, an AFM, or an EDX. In the film thickness measurement unit 638, the film thickness of the protective film 628 formed on the surfaces of the interconnects 626 is measured, and the substrate W after the film thickness measurement is returned to the substrate cassette 632 loaded on the loading/unloading unit by the transfer robot 634.

Measurement results obtained by off-line measurement of the film thickness of the protective film 628 formed on the exposed surfaces of the interconnects 626 are fed back before the electroless plating process to adjust, for example, processing time of plating for a subsequent substrate according to variations of the film thickness. Thus, the film thickness of the protective film 628 formed on the exposed surfaces of the interconnects 626 is measured, and, for example, processing time of plating for a subsequent substrate is adjusted according to variations of the film thickness. Accordingly, the film thickness of the protective film 628 formed on the exposed surfaces of the interconnects 626 can be controlled so as to be constant.

In this embodiment, copper is used as an interconnect material. However, copper alloy, silver, silver alloy, gold, gold alloy, or the like may be used as an interconnect material, instead of copper. Various materials can be used as an interconnect material. However, as described above, semiconductor devices that are required to protect interconnects 626 with a protective film 628 formed by electroless plating are generally limited to those which are highly integrated. By using copper, copper alloy, silver, or silver alloy as an interconnect material for semiconductor devices that are highly integrated, it is possible to increase the speed and the density of the semiconductor devices.

Further, for example, when copper, copper alloy, silver, or silver alloy is used as an interconnect material, then at least one of titanium, tantalum, tungsten, and compounds thereof is selected as a material for a barrier layer (barrier metal). The barrier layer includes a case in which a nitride of tantalum is formed at an interface with an insulating film, and a nitrogen content is reduced so as to eventually make a surface of the barrier layer tantalum.

In this embodiment, Co—W—P alloy is used as a protective film 628. However, Co, Co alloy, Ni, or Ni alloy may be used as a material having a function as a protective film to selectively cover and protect surfaces of interconnects. Specifically, in addition to Co—W—P alloy, a Co element or other Co alloys such as a Co—W—B alloy, a Co—P alloy, or a Co—B alloy may be used as a protective film 628. Further, a Ni element or Ni alloys such as a Ni—W—P alloy, a Ni—W—B alloy, a Ni—P alloy, or a Ni—B alloy may be used as a protective film.

Next, there will be described below details of various kinds of units provided in the substrate processing apparatus shown in FIG. 21. The first pre-treatment unit 642, the second pre-treatment unit 644, and the second plating unit 646 provided in the substrate processing apparatus shown in FIG. 21 have substantially the same structures as the first pre-treatment unit 18, the second pre-treatment unit 20, and the electroless plating unit 22 provided in the substrate processing apparatus shown in FIG. 2, respectively. Further, the rinsing and drying unit 645 and the cleaning unit 647 provided in the substrate processing apparatus shown in FIG. 21 are combined by the post-treatment and drying unit 400 shown in FIGS. 18 and 19. Accordingly, the first pre-treatment unit 642, the second pre-treatment unit 644, the second plating unit 646, the rinsing and drying unit 645, and the cleaning unit 647 will not be described repetitively.

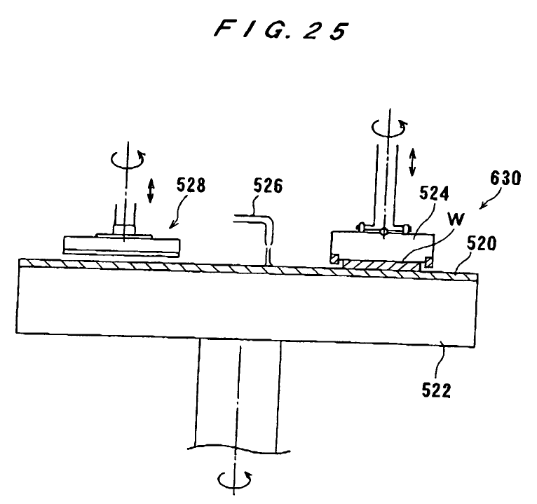

FIG. 25 shows an example of a CMP device as the polishing units 630. The polishing unit (CMP device) 630 has a polishing table 522 having a polishing surface composed of a polishing cloth (polishing pad) 520 which is attached to an upper surface of the polishing table 522, and a top ring 524 for holding a substrate W in a state such that a surface, to be polished, of the substrate W faces the polishing table 522. Polishing of the surface of the substrate W is carried out by rotating the polishing table 522 and the top ring 524, respectively, and supplying a polishing liquid (slurry) from a polishing liquid nozzle 526 provided above the polishing table 522 while pressing the substrate W against the polishing cloth 520 on the polishing table 522 at a predetermined pressure by the top ring 524. The CMP process is performed, for example, by using, as the polishing liquid supplied from the polishing liquid supply nozzle 526, slurry for copper polishing, and using the polishing cloth (polishing pad) 520 of a nonwoven fabric, a sponge, or a resin material such as foamed polyurethane.

Here, there is used, as the polishing liquid (slurry), a polishing liquid such that a surface potential when the barrier layer 620 is immersed therein is nobler than a surface potential when the interconnects 626 are immersed therein, or a polishing liquid such that a surface potential when the barrier layer 620 is immersed therein is less noble than a surface potential when the interconnects 626 are immersed therein. In the latter case, at the time of cleaning in the pre-treatment of the electroless plating, the substrate is processed (cleaned) with a treatment liquid such that a surface potential when the barrier layer 620 is immersed therein is nobler than a surface potential when the interconnects 626 are immersed therein. Accordingly, it is possible to prevent generation of defects D (see FIG. 23B) caused by corrosion at an interface between the barrier layer 620 and the interconnects 626 when a protective film 628 is formed selectively on surfaces of the interconnects 626 by electroless plating.

The polishing performance of the polishing surface of the polishing cloth 520 is lowered when the polishing operation is continuously performed by such a CMP device. In order to recover the polishing performance, a dresser 528 is provided. This dresser 528 conducts conditioning (dressing) of the polishing cloth 520 at the time of replacement of the polished substrate W. During the dressing process, while rotating the dresser 528 and the polishing table 522, respectively, a dressing surface (dressing member) of the dresser 528 is pressed against the polishing cloth 520 of the polishing table 522 to remove the polishing liquid and polishing wastes adhering to the polishing surface and, at the same time, to planarize and condition the polishing surface. Thus, the polishing surface is regenerated. A monitor for monitoring a state of a surface of a substrate may be provided in the polishing table 522 to detect an end point of polishing in situ. A monitor for inspecting a finish state of a substrate in situ may be provided in the polishing table 522.

There may be used a polishing unit in which a substrate and a conductive polishing tool are disposed in a polishing liquid so as to face each other, and the substrate serves as a polarized anode whereas the polishing tool serves as a polarized cathode, which is not shown. There may be used a polishing unit in which a substrate and a cathode are disposed in ultrapure water so as to face each other while an ion exchanger is interposed between the substrate and the cathode, and the substrate serves as a polarized anode.

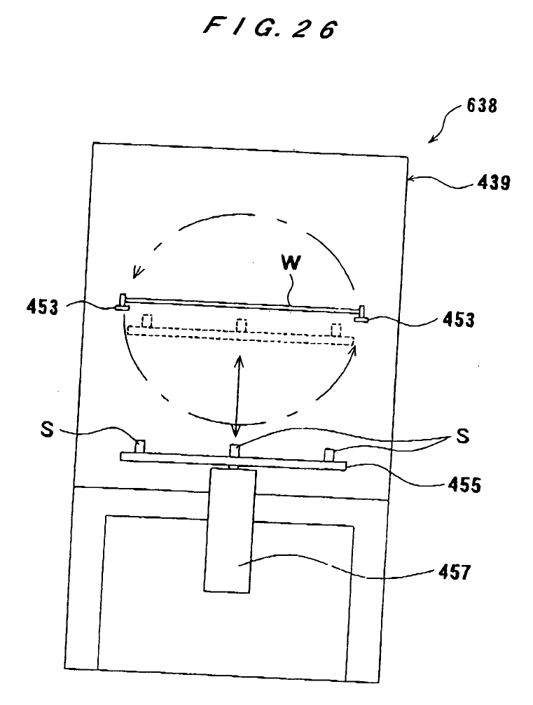

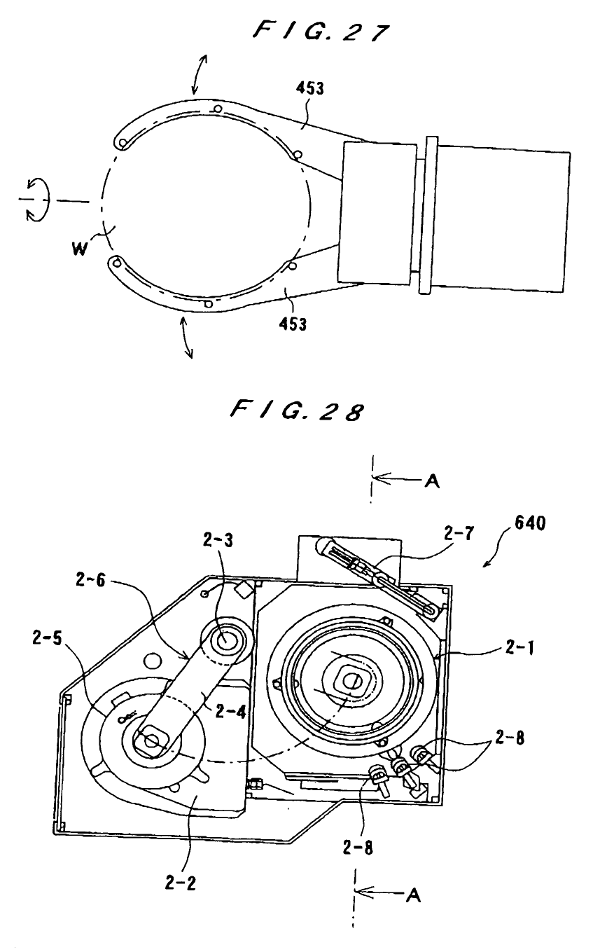

FIGS. 26 and 27 show the film thickness measurement unit 638 having a reversing machine. As shown in the FIGS. 26 and 27, the film thickness measuring unit 638 is provided with a reversing machine 439. The reversing machine 439 includes reversing arms 453 and 453. The reversing arms 453 and 453 have functions to put a substrate W therebetween, hold its outer periphery from right and left sides, and rotate the substrate W through 180° to thereby turn over the substrate W. A circular mounting base 455 is disposed right below the reversing arms 453 and 453 (reversing stages), and a plurality of film thickness sensors S are provided on the mounting base 455. The mounting base 455 is adapted to be vertically movable by a drive mechanism 457.

When the substrate W is reversed, the mounting base 455 waits at a position, indicated by solid lines, below the substrate W. Before or after the reversing, the mounting base 455 is lifted up to a position indicated by dotted lines to bring the film thickness sensors S close to the substrate W held by the reversing arms 453 and 453, so that the film thickness is measured.

According to this embodiment, since there is no restriction such as the arms of the transfer robot, the film thickness sensors S can be installed at desired positions on the mounting base 455. Further, since the mounting base 455 is adapted to be vertically movable, a distance between the substrate W and the sensors S can be adjusted at the time of measurement. It is also possible to mount a plurality of types of sensors suitable for purposes of detection and change a distance between the substrate W and the sensors each time measurement is performed by the respective sensors. However, since the mounting base 455 is vertically moved, a certain period of measuring time is required.

For example, an eddy current sensor may be used as the film thickness sensor S. The eddy current sensor generates an eddy current and detects the frequency or loss of the current that has returned through the substrate W to measure a film thickness. The eddy current sensor is used in a non-contact manner. An optical sensor may also be suitable for the film thickness sensor S. The optical sensor irradiates light onto a sample and measures a film thickness directly based on information of the reflected light. The optical sensor can measure a film thickness not only of a metal film but also of an insulating film such as an oxide film Mounting positions of the film thickness sensors S are not limited to those shown in the drawings, and a desired number of sensors may be mounted at any desired positions for measurement.

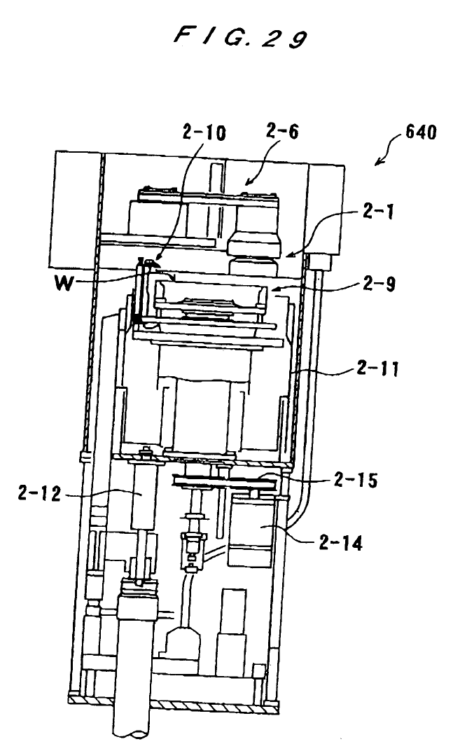

FIGS. 28 through 33 show an electroplating device for forming the first plating unit 640. As shown in FIG. 28, the plating device (electroplating device) 640 is provided with a substrate treatment section 2-1 for performing a plating process and an accessory process. A plating solution tray 2-2 for storing a plating solution is disposed adjacent to the substrate treatment section 2-1. There is also provided an electrode arm portion 2-6 having an electrode portion 2-5 which is held at a tip end of a swingable arm 2-4 swingable about a rotating shaft 2-3 and which is swung between the substrate treatment section 2-1 and the plating solution tray 2-2.

Further, a precoat and recovery arm 2-7 and fixed nozzles 2-8 for ejecting pure water, a chemical liquid such as ion water, a gas, or the like toward a substrate are disposed beside the substrate treatment section 2-1. In this embodiment, three fixed nozzles 2-8 are disposed. One of the fixed nozzles 2-8 is used for supplying pure water. As shown in FIGS. 17 and 18, the substrate treatment section 2-1 has a substrate holding portion 2-9 for holding a substrate W in a state such that a surface to be plated faces upward, and a cathode portion 2-10 located above the substrate holding portion 2-9 so as to surround a peripheral portion of the substrate holding portion 2-9. Further, a substantially cylindrical bottomed cup 2-11 surrounding a periphery of the substrate holding portion 2-9 for preventing scatter of various kinds of chemical liquids used during the treatment is provided so as to be vertically movable by an air cylinder 2-12.

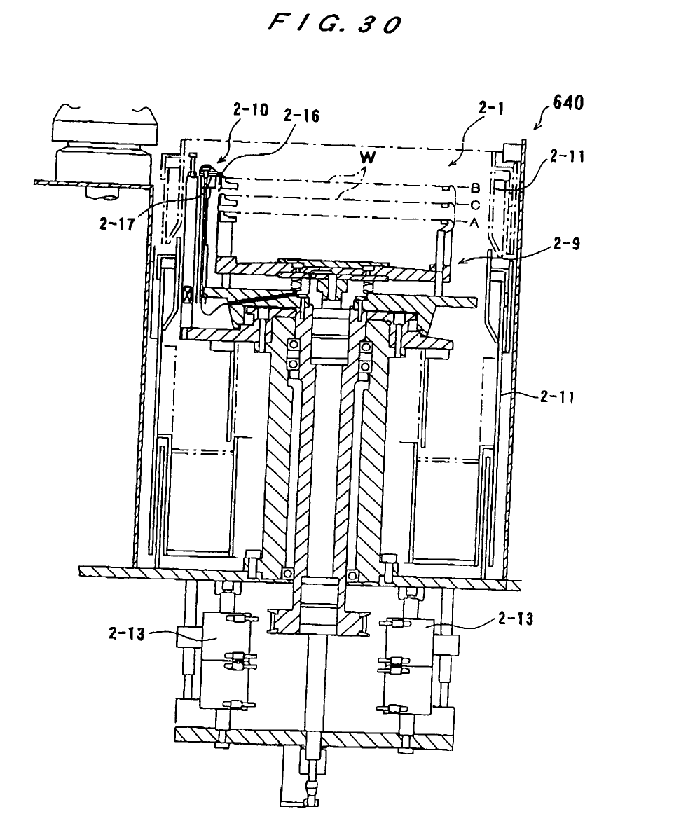

The substrate holding portion 2-9 is adapted to be lifted and lowered by the air cylinder 2-12 between a lower substrate delivery position A, an upper plating position B, and a pre-treatment and cleaning position C intermediate between the substrate delivery position A and the plating position B. The substrate holding portion 2-9 is also adapted to rotate at a desired acceleration and speed integrally with the cathode portion 2-10 via a rotating motor 2-14 and a belt 2-15. A substrate transfer opening (not shown) is provided near the transferring robot 34 (see FIG. 21) in a frame side surface of the electroplating device so as to face the substrate delivery position A. When the substrate holding portion 2-9 is lifted up to the plating position B, a seal member 2-16 and a cathode electrode 2-17 of the cathode portion 2-10 are brought into contact with the peripheral edge portion of the substrate W held by the substrate holding portion 2-9. Meanwhile, an upper end of the cup 2-11 is located below the substrate transfer opening. When the cup 2-11 is lifted up, the upper end of the cup 2-11 reaches a position above the cathode portion 2-10, as shown by imaginary lines in FIG. 30.

When the substrate holding portion 2-9 is lifted up to the plating position B, the cathode electrode 2-17 is pressed against the peripheral edge portion of the substrate W held by the substrate holding portion 2-9 to supply an current to the substrate W. At the same time, an inner peripheral end portion of the seal member 2-16 is brought into contact with an upper surface of the peripheral edge of the semiconductor substrate W under pressure to seal the contact portion in a watertight manner As a result, the plating solution supplied onto the upper surface of the semiconductor substrate W is prevented from seeping from the end portion of the semiconductor substrate W and from contaminating the cathode electrode 2-17.

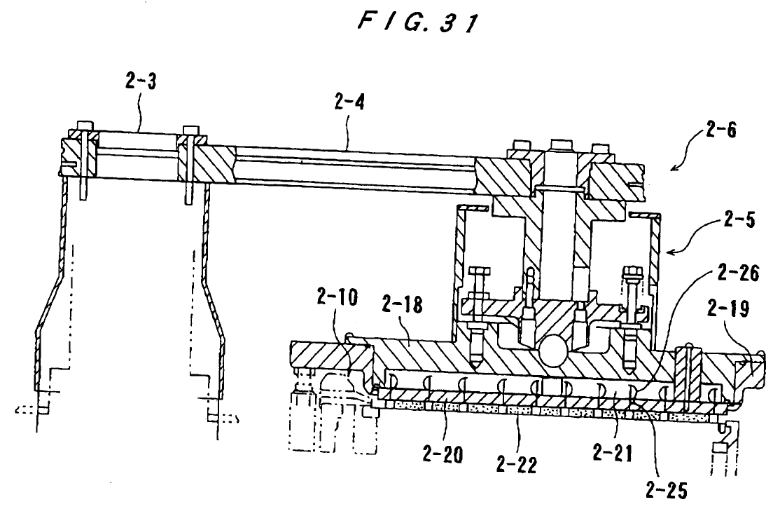

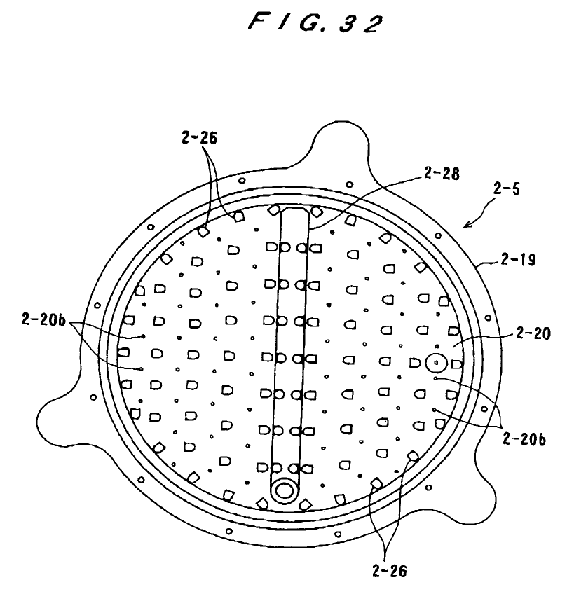

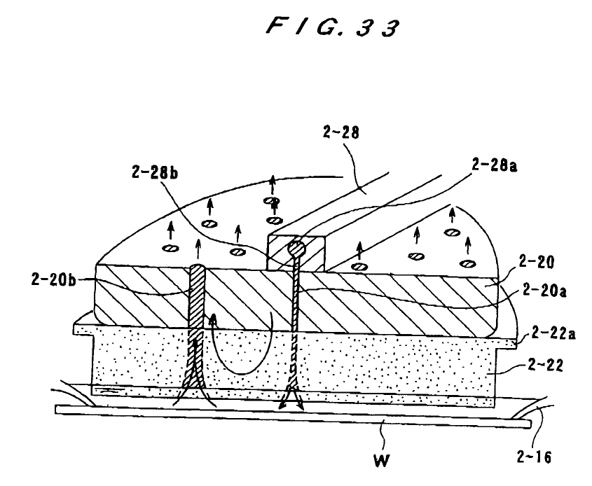

As shown in FIG. 31, the electrode portion 2-5 of the electrode arm portion 2-6 has a housing 2-18 at a free end of the swingable arm 24, a hollow support frame 2-19 surrounding the housing 2-18, and an anode 2-20 fixed by holding the peripheral edge portion of the anode 2-20 between the housing 2-18 and the support frame 2-19. The anode 2-20 covers an opening portion of the housing 2-18, and a suction chamber 2-21 is formed inside the housing 2-18. Further, as shown in FIGS. 32 and 33, a plating solution introduction pipe 2-28 and a plating solution discharge pipe (not shown) for introducing and discharging the plating solution are connected to the suction chamber 2-21. Further, a large number of passage holes 2-20b communicating with regions above and below the anode 2-20 are provided over an entire surface of the anode 2-20.

In this embodiment, a plating solution impregnated material 2-22 comprising a water retention material and covering the entire surface of the anode 2-20 is attached to a lower surface of the anode 2-20. The plating solution impregnated material 2-22 is impregnated with the plating solution to wet the surface of the anode 2-20 to thereby prevent a black film from falling onto the plated surface of the substrate and simultaneously facilitate escape of air to the outside when the plating solution is poured between the surface, to be plated, of the substrate and the anode 2-20. For example, the plating solution impregnated material 2-22 is formed by a woven fabric, a nonwoven fabric, or sponge-like structure comprising at least one material of polyethylene, polypropylene, polyester, polyvinyl chloride, Teflon (registered trademark), polyvinyl alcohol, polyurethane, and derivatives of these materials, or formed by a porous ceramics.

Attachment of the plating solution impregnated material 2-22 to the anode 2-20 is performed as follows Specifically, a large number of fixing pins 2-25 each having a head portion at the lower end thereof are arranged such that the head portion is housed in the plating solution impregnated material 2-22 so as not to be releasable upward and a shaft portion of the fixing pin 2-25 extends through the anode 2-20. The fixing pins 2-25 are urged upward by U-shaped plate springs 2-26, so that the plating solution impregnated material 2-22 is brought into close contact with the lower surface of the anode 2-20 by elastic forces of the leaf springs 2-26. With this arrangement, even when the thickness of the anode 2-20 is gradually reduced according to progress of plating, the plating solution impregnated material 2-22 can be reliably brought into close contact with the lower surface of the anode 2-20. Accordingly, air is prevented from entering between the lower surface of the anode 2-20 and the plating solution impregnated material 2-22 to cause plating defects.

Columnar pins made of PVC (polyvinyl chloride) or PET (polyethylene terephthalate) which have a diameter of, for example, about 2 mm may be disposed so as to extend through the anode and from the upper surface of the anode, and an adhesive may be applied to a tip end surface of each of the pins projecting from the lower surface of the anode to fix the anode to the plating solution impregnated material. The anode and the plating solution impregnated material may be used in contact with each other. However, a gap may be formed between the anode and the plating solution impregnated material, and a plating process may be performed while the plating solution is held in the gap. This gap is selected from a range of 20 mm or less However, the gap is preferably selected from a range of 0.1 to 10 mm, and more preferably 1 to 7 mm. Particularly, when a soluble anode is used, the anode is dissolved from a lower portion of the anode. Accordingly, as time elapses, the gap between the anode and the plating solution impregnated material is increased so as to be in a range of 0 to about 20 mm.

The electrode portion 2-5 is lowered to a degree such that when the substrate holding portion 2-9 is located at the plating position B (see FIG. 30), the gap between the substrate W held by the substrate holding portion 2-9 and the plating solution impregnated material 2-22 is in a range of about 0.1 to 10 mm, preferably 0.3 to 3 mm, and more preferably about 0.5 to 1 mm. In this state, the plating solution is supplied from a plating solution supply pipe to fill a space between the upper surface (surface to be plated) of the substrate W and the anode 2-20 with the plating solution while the plating solution impregnated material 2-22 is impregnated with the plating solution. The surface, to be plated, of the substrate W is plated by applying a voltage from a power source between the upper surface (surface to be plated) of the substrate W and the anode 2-20.

Next, there will be described the plating process performed in the plating unit (electroplating device) 640.

First, a substrate W to be plated is transferred by the transfer robot 34 (see FIG. 21) to the substrate holder 2-9 located at the substrate delivery position A and placed on the substrate holder 2-9. Then, the cup 2-11 is lifted up and, at the same time, the substrate holder 2-9 is lifted up to the pre-treatment and cleaning position C. In this state, the precoat and recovery arm 2-7 in the retracting position is moved to a position where the precoat and recovery arm 2-7 faces the substrate W, and a precoating solution of, for example, a surface-active agent is intermittently ejected from a precoating nozzle provided at the tip end of the precoat and recovery arm 2-7 onto the surface, to be plated, of the substrate W. At that time, the substrate holder 2-9 is rotated. Accordingly, the precoating solution can spread over an entire surface of the substrate W. Then, the precoat and recovery arm 2-7 is returned to the retracting position, and the rotating speed of the substrate holder 2-9 is increased so as to scatter the precoating solution on the surface, to be plated, of the substrate W by centrifugal forces to thereby dry the substrate.

Subsequently, after the substrate holder 2-9 is lifted up to the plating position B (see FIG. 30), the electrode arm section 2-6 is horizontally swung so that the electrode portion 2-5 is moved from above the plating solution tray 2-2 to above a position for plating. The electrode portion 2-5 is lowered toward the cathode portion 2-10 at that position. After lowering of the electrode portion 2-5 is completed, a plating voltage is applied between the anode 2-20 and the cathode portion 2-10 while a plating solution is supplied into the electrode portion 2-5 so that the plating solution is supplied to the plating solution impregnated material 2-22 through a plating solution supply port extending through the anode 2-20. At that time, the plating solution impregnated material 2-22 is not brought into contact with the surface, to be plated, of the substrate W but is close to the surface, to be plated, of the substrate W at a distance of about 0.1 to 10 mm, preferably about 0.3 to 3 mm, more preferably about 0.5 to 1 mm.

When supply of the plating solution is continued, the plating solution containing copper ions which oozes out of the plating solution impregnated material 2-22 is filled in a space between the plating solution impregnated material 2-22 and the surface, to be plated, of the substrate W, to thereby carry out copper plating on the surface, to be plated, of the substrate W. At that time, the substrate holder 2-9 may be rotated at a low speed.

After completion of the plating process, the electrode arm section 2-6 is lifted up and then swung so that the electrode portion 2-5 is returned to above the plating solution tray 2-2. Thereafter, the electrode portion 2-5 is lowered to the normal position. Next, the precoat and recovery arm 2-7 is moved from the retracting position to a position at which the precoat and recovery arm 2-7 faces the substrate W and then lowered the plating solution remaining on the substrate W is recovered through a plating solution recovery nozzle (not shown). After completion of recovery of the remaining plating solution, the precoat and recovery arm 2-7 is returned to the retracting position. Thereafter, pure water is ejected toward the center of the substrate W and, at the same time, the substrate holder 2-9 is rotated while a speed of the substrate holder 2-9 is increased, to thereby replace the plating solution on the surface of the substrate W with pure water.

After the rinsing, the substrate holder 2-9 is lowered from the plating position 13 to the pre-treatment and cleaning position C, and water washing is carried out by supplying pure water from the fixed nozzle 2-8 for pure water while the substrate holder 2-9 and the cathode portion 2-10 are rotated. At that time, the sealing member 2-16 and the cathode electrode 2-17 can also be cleaned together with the substrate W by pure water supplied directly to the cathode portion 2-10 or by pure water scattered from the surface of the substrate W.

After completion of the water washing, supply of pure water from the fixed nozzle 2-8 is stopped, and the rotational speed of the substrate holder 2-9 and the cathode portion 2-10 is increased to scatter the pure water on the surface of the substrate W by centrifugal forces to thereby dry the substrate. Simultaneously, the sealing member 2-16 and the cathode electrode 2-17 can also be dried. After completion of the drying, the rotation of the substrate holder 2-9 and the cathode portion 2-10 is stopped, and the substrate holder 2-9 is lowered to the substrate delivery position A.

In the above embodiment, there has been described the first plating unit 640 which has a plating solution impregnated material for holding a plating solution and holds a substrate in a face-up manner so as to carry out plating on a front face (upper surface) of the substrate. For example, there may be used a plating unit which holds a substrate in a face-down manner and brings a front face (upper surface) of the substrate into contact with a plating solution to carry out plating.

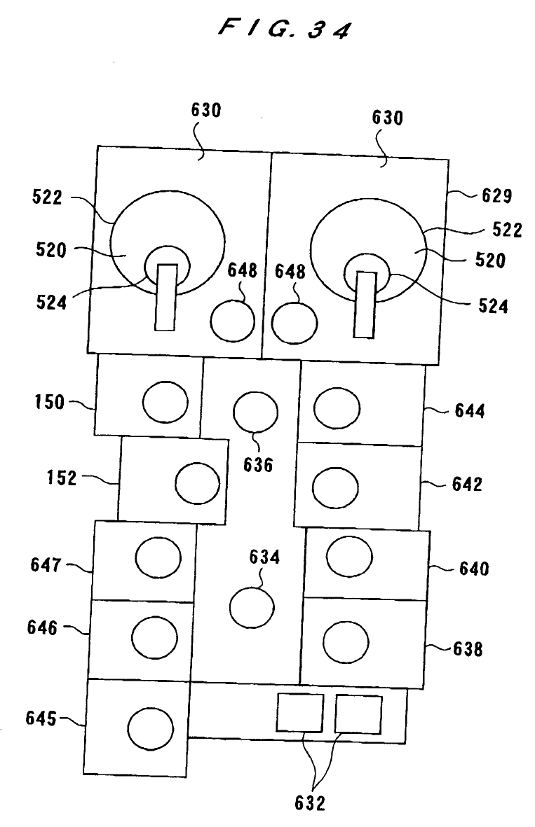

FIG. 34 is a horizontal arrangement view of another example of a substrate processing apparatus (manufacturing apparatus for semiconductor devices). The substrate processing apparatus has a bevel etching unit 150 and a heat treatment (annealing) unit 152 disposed between a polishing unit 630 and a cleaning unit 647. A first transfer robot 634 transfers a substrate between substrate cassettes 632 received in loading/unloading sections, a film thickness measurement unit 638, a first plating unit 640, a rinsing and drying unit 645, a second plating unit 646, and the cleaning unit 647. A second transfer robot 636 transfers a substrate between a first pre-treatment unit 642, a second pre-treatment unit 644, the polishing unit 630, the bevel etching unit 150, and the heat treatment unit 152. Other configurations are the same as those shown in FIG. 21 and will not be described repetitively.

According to this embodiment, a substrate in which a copper layer 624 is deposited on a surface of the substrate to embed copper as described above is transferred to the bevel etching unit 150. In the bevel etching unit 150, an unnecessary interconnect material, which is attached to a bevel portion or an edge portion of the substrate, is etched and removed. Further, a rear face of the substrate is cleaned with a chemical liquid as needed. Then, the substrate is transferred to the heat treatment unit 152, where a heat treatment (annealing) is performed, for example, at 300 to 400° C. for 1 to 5 minutes. Thereafter, the annealed substrate is transferred to the first pre-treatment unit 642 as described above, and the same treatment as described above is performed therein. According to this embodiment, a series of operations including a bevel etching process and an annealing process can be performed continuously.

As described above, according to the present invention, it is possible to continuously perform a series of operations for forming a protective film on exposed surfaces of embedded interconnects formed in a surface of a substrate by electroless plating. Further, since the substrate is finished to a dry state, the substrate can be transferred directly to a subsequent process, and simultaneously degradation of the protective film (plated film) can be prevented before the subsequent process. Thus, the reproducibility can be achieved over a surface of a substrate such as a semiconductor wafer and between substrates, and semiconductor devices or the like can be manufactured with a high yield.

What is claimed is:

1. A substrate processing method of forming a protective film selectively on bottom surfaces and side surfaces or exposed surfaces of embedded interconnects formed in a surface of a substrate, said substrate processing method characterized by:
performing a pre-plating process on the substrate;
carrying out electroless plating on the surface of the substrate after said pre-plating process to form the protective film selectively on the bottom surfaces and the side surfaces or the exposed surfaces of the interconnects; and
bringing the substrate into a dry state after said electroless plating.

2. The substrate processing method as recited in claim 1, characterized in that the substrate to be subjected to said pre-plating process is introduced in a dry state.

3. The substrate processing method as recited in claim 1, characterized by performing a post-treatment on the substrate after said electroless plating to improve selectivity of the protective film, and then bringing the substrate into a dry state.

4. The substrate processing method as recited in claim 1, characterized in that said pre-plating process includes a process to clean the surface of the substrate, and a process to apply a catalyst to an underlying surface, to be plated, of the substrate to activate the underlying surface to be plated after said cleaning.

5. The substrate processing method as recited in claim 4, characterized by performing planarization of the exposed surfaces of the interconnects by either one of chemical mechanical polishing, electrochemical polishing, or composite electrochemical polishing prior to said process of cleaning the surface of the substrate.

6. The substrate processing method as recited in claim 4, characterized in that said cleaning process of the surface of the substrate comprises performing a plasma treatment on the substrate under a decompressed atmosphere or an atmospheric pressure.

7. The substrate processing method as recited in claim 4, characterized in that said activation process of the underlying surface to be plated is performed by light irradiation, a CVD method, or a PVD method.

8. The substrate processing method as recited in claim 4, characterized in that said cleaning process of the surface of the substrate comprises bringing the surface of the substrate into contact with a chemical liquid of an inorganic acid having a pH below 2, an acid having a pH below 5 and a chelating capability, a solution having a pH below 5 to which a chelating agent is added, an alkali solution capable of removing an anticorrosive attached to the interconnects, or an alkali solution containing an amino acid, and then performing a rinsing process on the surface of the substrate with a rinsing liquid after said cleaning.

9. The substrate processing method as recited in claim 8, characterized in that the rinsing liquid comprises pure water, hydrogen gas dissolved water, or electrolytic cathode water.

10. The substrate processing method as recited in claim 4, characterized in that said application of the catalyst to the underlying surface to be plated comprises bringing the underlying surface to be plated into contact with a chemical liquid containing palladium, and then performing a rinsing process on the surface of the substrate with a rinsing liquid after said catalyst application.

11. The substrate processing method as recited in claim 10, characterized in that the rinsing liquid comprises pure water, hydrogen gas dissolved water, electrolytic cathode water, or an aqueous solution containing a component in a plating solution used for said electroless plating.

12. The substrate processing method as recited in claim 4, characterized in that the catalyst is applied to the underlying surface to be plated so that the underlying surface to be plated has a palladium catalyst concentration of 0.4 to 8 μg per 1 cm².

13. The substrate processing method as recited in claim 4, characterized by measuring an amount of chemical liquid used for said pre-plating process, analyzing composition in the pre-treatment liquid, and replenishing an insufficient component in the pre-treatment liquid.

14. The substrate processing method as recited in claim 1, characterized in that a deposition rate of the protective film by said electroless plating is in a range of 10 to 200 Å per minute.

15. The substrate processing method as recited in claim 1, characterized in that said deposition of the protective film by said electroless plating comprises bringing the substrate into contact with a plating solution having a pH of 7 to 10 and including alkali metal but no ammonia.

16. The substrate processing method as recited in claim 15, characterized in that the plating solution contains tungsten in concentration of at least 1.5 g/L.

17. The substrate processing method as recited in claim 1, characterized in that the protective film comprises an alloy film containing three elements of cobalt, tungsten, and phosphorus.

18. The substrate processing method as recited in claim 17, characterized in that an average composition of the alloy film is in a range of 75 to 90 atomic % of cobalt, 1 to 10 atomic % of tungsten, and 5 to 25 atomic % of phosphorus.

19. The substrate processing method as recited in claim 15, characterized by measuring an amount of the plating solution, analyzing composition in the plating solution, and replenishing an insufficient component in the plating solution.

20. The substrate processing method as recited in claim 15, characterized by measuring a dissolved oxygen concentration in the plating solution and controlling the dissolved oxygen concentration to be constant.

21. The substrate processing method as recited in claim 1, characterized by lifting up the substrate from the plating solution after said electroless plating process, and bringing the surface of the substrate into contact with a stop solution of a neutral liquid having a pH of 6 to 7.5 to stop plating reaction.

22. The substrate processing method as recited in claim 21, characterized in that the stop solution comprises pure water, hydrogen gas dissolved water, or electrolytic cathode water.

23. The substrate processing method as recited in claim 3, characterized in that said post-treatment of the substrate comprises rubbing the surface, to be treated, of the substrate with a surface of a cylindrical cleaning member while rotating the cleaning member about its axis.

24. The substrate processing method as recited in claim 3, characterized in that said post-treatment of the substrate comprises performing planarization of the plated surface by either one of chemical mechanical polishing, electrochemical polishing, or composite electrochemical polishing.

25. The substrate processing method as recited in claim 3, characterized in that said post-treatment of the substrate uses a chemical liquid containing one or at least two of a surface-active agent, an organic alkali, and chelating agent.

26. The substrate processing method as recited in claim 3, characterized by rinsing the substrate with pure water, hydrogen gas dissolved water, or electrolytic cathode water after said post-treatment of the substrate, and then drying the substrate.

27. The substrate processing method as recited in claim 1, characterized by controlling humidity of an atmosphere around the substrate by using dry air or dry inert gas when a drying process is performed to bring the substrate into a dry state.

28. The substrate processing method as recited in claim 1, characterized by performing a heat treatment on the dried substrate to reform the protective film.

29. The substrate processing method as recited in claim 28, characterized in that temperature of said heat treatment is in a range of 120 to 450° C.

30. The substrate processing method as recited in claim 1, characterized by measuring film thickness of the protective film formed on a plated underlying surface.

31. A substrate processing apparatus characterized by comprising:
a pre-treatment unit for performing a pre-plating process on a surface of a substrate;
an electroless plating unit for carrying out electroless plating on the surface of the substrate after the pre-plating process to form a protective film selectively on bottom surfaces and side surfaces or exposed surfaces of interconnects; and
a drying unit for bringing the substrate into a dry state after The electroless plating process.

32. The substrate processing apparatus as recited in claim 31, characterized by comprising a post-treatment unit disposed between said electroless plating unit and said drying unit for performing a post-treatment to improve selectivity of the protective film formed on the surface of the substrate.

33. The substrate processing apparatus as recited in claim 31, characterized in that said pre-treatment unit has a first pre-treatment unit for treating the surface of the substrate with a chemical liquid and removing the chemical liquid from the surface of the substrate, and a second pre-treatment unit for applying a catalyst to the surface of the substrate and removing a chemical liquid used for catalyst application from the surface of the substrate.

34. The substrate processing apparatus as recited in claim 31, characterized in that said pre-treatment unit is configured to eject a chemical liquid toward the substrate through a spray.

35. The substrate processing apparatus as recited in claim 31, characterized by comprising a pre-treatment liquid management unit for measuring an amount of pre-treatment liquid held in said pre-treatment unit, analyzing composition in the pre-treatment liquid, and replenishing an insufficient component in the pre-treatment liquid.

36. The substrate processing apparatus as recited in claim 31, characterized in that said electroless plating unit has a plating tank, a plating solution circulating system, and a plating solution reservoir tank, wherein said plating solution circulating system can circulate a plating solution between said plating tank and said plating solution reservoir tanl at flow rates which can be set independently at the time of a standby of plating and at the time of a plating process, wherein an amount of plating solution circulated at the time of the standby of plating is in a range of 2 to 20 L/min, and an amount of plating solution circulated at the time of the plating process is in a range of 0 to 10 L/min.

37. The substrate processing apparatus as recited in claim 31, characterized by comprising a plating solution management unit for measuring an amount of plating solution held in said electroless plating unit, analyzing composition in the plating solution, and replenishing an insufficient component in the plating solution.

38. The substrate processing apparatus as recited in claim 37, characterized in that said plating solution management unit has a dissolved oxygen concentration meter for measuring dissolved oxygen in the plating solution held in said electroless plating unit, and controls dissolved oxygen concentration of the plating solution so as to be constant based on indication of said dissolved oxygen concentration meter.

39. The substrate processing apparatus as recited in claim 32, characterized in that said post-treatment unit employs at least one of roll scrubbing cleaning, pencil cleaning, or etching back with an etching liquid.

40. The substrate processing apparatus as recited in claim 32, characterized in that said post-treatment unit is formed by at least one of a chemical mechanical polishing unit, an electrochemical polishing unit, and a composite electrochemical polishing unit.

41. The substrate processing apparatus as recited in claim 31, characterized in that said drying unit comprises a spin-drier.

42. The substrate processing apparatus as recited in claim 31, characterized in that said drying unit has a dry air unit for supplying dry air to said drying unit or a dry inert gas unit for supplying dry inert gas to said drying unit.

43. The substrate processing apparatus as recited in claim 31, characterized by comprising a heat treatment unit for performing a heat treatment on the substrate dried in said drying unit to reform the protective film.

44. The substrate processing apparatus as recited in claim 31, characterized by comprising a film thickness measurement unit for measuring film thickness of the protective film formed on the plated underlying surface.

45. The substrate processing apparatus as recited in claim 31, characterized by comprising a device for dissolving hydrogen gas in ultrapure water or a device for electrolyzing ultrapure water to supply hydrogen gas dissolved water or electrolytic cathode water to said respective units.

46. A substrate processing method characterized by:
embedding an interconnect material in interconnect recesses formed in an insulating film on a substrate and having a barrier layer deposited thereon, removing an excess interconnect material for planarization to form embedded interconnects on a surface of the substrate;
cleaning the planarized substrate immediately after a pre-plating process;
carrying out electroless plating on the surface of the substrate immediately after said cleaning to form a protective film selectively on exposed surfaces of the interconnects; and
bringing the substrate into a dry state after said electroless plating.

47. The substrate processing method as recited in claim 46, characterized in that the substrate to be subjected to said pre-plating process is brought into a dry state after said planarization.

48. The substrate processing method as recited in claim 46, characterized by cleaning the substrate immediately after said planarization, and performing a pre-plating process on the substrate immediately after said cleaning.

49. The substrate processing method as recited in claim 48, characterized in that the substrate to be subjected to said planarization process is brought into a dry state after the interconnect material has been embedded in said interconnect recesses in the substrate.

50. The substrate processing method as recited in claim 46, characterized in that the interconnect material comprises copper, copper alloy, silver, or silver alloy.

51. The substrate processing method as recited in claim 46, characterized in that the barrier layer is made of at least one of titanium, tantalum, tungsten, and a compound thereof.

52. The substrate processing method as recited in claim 46, characterized in that the protective film is made of cobalt, cobalt alloy, nickel, or alloy of nickel.

53. The substrate processing method as recited in claim 46, characterized in that cleaning the substrate after said planarization and/or after said pre-plating process is carried out by using a cleaning liquid such that a potential difference between the exposed surfaces of the interconnects and an exposed surface of the barrier layer is not more than 200 mV when the substrate is immersed therein.

54. The substrate processing method as recited in claim 53, characterized in that the cleaning liquid comprises ultrapure water from which dissolved oxygen is removed.

55. The substrate processing method as recited in claim 53, characterized in that the cleaning liquid comprises ultrapure water in which hydrogen gas is dissolved.

56. The substrate processing method as recited in claim 46, characterized in that said removing the excess interconnect material for planarization is carried out by a chemical mechanical polishing method using a polishing liquid such that a surface potential when the barrier layer is immersed therein is nobler than a surface potential when the interconnect material is immersed therein.

57. The substrate processing method as recited in claim 46, characterized in that said removing the excess interconnect material for planarization is carried out by a chemical mechanical polishing method using a polishing liquid such that a surface potential when the barrier layer is immersed therein is less noble than a surface potential when the interconnect material is immersed therein, and in said pre-plating process before said electroless plating, the substrate is treated with a treatment liquid such that a surface potential when the barrier layer is immersed therein is nobler than a surface potential when the interconnect material is immersed therein.

58. The substrate processing method as recited in claim 46, characterized in that said removing the excess interconnect material for planarization includes a process of disposing a substrate and a conductive polishing tool in a polishing liquid so as to face each other, and treating the substrate while the substrate serves as a polarized anode whereas the polishing tool serves as a polarized cathode.

59. The substrate processing method as recited in claim 46, characterized in that said removing the excess interconnect material for planarization includes a process of disposing a substrate and a cathode in ultrapure water so as to face each other while an ion exchanger is interposed between the substrate and the cathode, and treating the substrate while the substrate serves as a polarized anode.

60. The substrate processing method as recited in claim 46, characterized in that at least one of said respective processes and transferring processes therebetween is performed in a shaded state.

61. A substrate processing apparatus characterized by comprising:
a planarization unit for removing an excess interconnect material and a barrier layer deposited on a portion other than interconnect recesses for planarization in a surface of a substrate, the barrier layer being deposited on surfaces of the interconnect recesses, the interconnect material being embedded in the interconnect recesses to form embedded interconnects on the surface of the substrate;
a cleaning unit for cleaning the substrate after the planarization;
a pre-treatment unit for performing a pre-plating process on the surface of the cleaned substrate;
an electroless plating unit for carrying out electroless plating on the surface of the substrate after the pre-treatment to form the protective film selectively on exposed surfaces of the embedded interconnects; and
a drying unit for bringing the substrate into a dry state after the electroless plating process.

62. The substrate processing apparatus as recited in claim 61, characterized by a post-treatment unit disposed between said electroless plating unit and said drying unit for performing a post-treatment to improve selectivity of the protective film formed on the surface of the substrate

63. The substrate processing apparatus as recited in claim 61, characterized in that said pre-treatment unit has a first pre-treatment unit for treating the surface of the substrate with a chemical liquid and removing the chemical liquid from the surface of the substrate, and a second pre-treatment unit for applying a catalyst to the surface of the substrate and removing a chemical liquid used for catalyst application from the surface of the substrate.

64. The substrate processing apparatus as recited in claim 61, characterized in that said planarization unit is formed by at least one of a chemical mechanical polishing unit, an electrochemical polishing unit, and a composite electrochemical polishing unit.

65. The substrate processing apparatus as recited in claim 61, characterized by a deposition unit for depositing an interconnect material on the interconnect recesses in the surface of the substrate prior to said planarization unit.

66. The substrate processing apparatus as recited in claim 65, characterized in that said deposition unit comprises at least a plating unit.
